(19) United States
(12) Patent Application Publication
(10) Pub. No.: US 2012/0064690 A1
(43) Pub. Date: Mar. 15, 2012

(54) METHOD FOR MANUFACTURING SEMICONDUCTOR DEVICE

(75) Inventors: Toshiyuki HIROTA, Tokyo (JP); Takakazu KIYOMURA, Tokyo (JP)

(73) Assignee: ELPIDA MEMORY, INC., Tokyo (JP)

(21) Appl. No.: 13/227,788

(22) Filed: Sep. 8, 2011

(30) Foreign Application Priority Data
Sep. 10, 2010 (JP) 2010-202854

(51) Int. Cl. H01L 21/02

(52) U.S. Cl. 438/381; 257/E21.011

(57) ABSTRACT

A method for manufacturing a semiconductor device includes at least forming a lower electrode made of titanium nitride on a semiconductor substrate, forming a dielectric film comprising zirconium oxide, in which at least the uppermost layer of the dielectric film is formed by an atomic layer deposition (ALD) method on the lower electrode, forming a first protective film on the dielectric film without exceeding the film forming temperature of the ALD method over 70° C., and forming an upper electrode made of a titanium nitride on the first protective film.

### BACKGROUND OF THE INVENTION

1. Field of Invention

The present invention relates to a semiconductor device and a method of manufacturing the same, and, in particular, to dynamic random access memory (DRAM) having a capacitor with properties of low leakage current and high permittivity.

2. Description of Related Arts

DRAM has been used for a semiconductor memory operable at a high speed in a computer or other electronic devices. DRAM has a memory cell array and a peripheral circuit for operating the array. The memory cell array has a plurality of units arranged in a matrix, and each unit comprises one switching transistor and one capacitor.

As in other semiconductor devices, DRAM has developed with miniaturization of each cell to satisfy a demand for high-integration. As a result, the area on which a capacitor is formed decreases, and it is thus difficult to ensure the capacity required for a memory device. To solve this problem, a three-dimensional structure of electrodes, upper and lower electrodes made of a metallic material (MIM structure), a capacitive insulation film having high permittivity, etc have been introduced. Currently, DRAM with a minimum feature size (F value) of 70 nm or less, which is used as a standard index of a technology level, necessarily has a three-dimensional electrode structure, and upper and lower electrodes made of a metallic material have already been used in practice. Therefore, the prospect of improving the features of a capacitor on the basis of these technical developments is bleak. The current trend of additional miniaturization mainly includes improving the feature of a capacitor by high permittivity of a capacitive insulation film left for the last.

The characteristics required for a capacitor in a semiconductor memory device include (1) a large capacity, i.e., high permittivity (or a small EOT as described later), (2) small leakage current in a capacitive insulation film. However, it is well known that a dielectric film with high permittivity has small resistance to dielectric breakdown and has high leakage current. In other words, high permittivity and low leakage current are in trade-off relation. To accomplish a more miniaturized memory cell, there has been demand for a capacitor structure, and a method for manufacturing the structure, having reliability without increasing leakage current even if a dielectric film with high permittivity is used.

WO 2009/090979 discloses a way to prevent leakage current in a structure where an STO (strontium titanium oxide) film is used and a TiN (titanium nitride) is used for upper and lower electrodes. Specifically, it discloses a flat capacitor structure where a buffer electrode layer, which is made of an amorphous conductor such as TiSiN (titanium silicon nitride), is interposed between the lower electrode and a dielectric, and between the dielectric and the upper electrode. The unevenness of the surface of the lower electrode decreases by covering the lower electrode using an amorphous conductor in the buffer electrode, and leakage current is thought to be reduced accordingly.

A capacitor with a MIM structure, e.g., a structure of TiN/ZrO₂/TiN, has been used as a DRAM capacitor.

DRAM is formed from heat treatment at 450° C. to 500° C. as an unavoidable process after a capacitor has been formed. However, a dielectric film composed of a single layer of zirconium oxide cannot achieve a sufficient thermostability, and leakage current likely increases after heat treatment.

Therefore, several attempts have been made to increase thermostability, and the examples of such attempts include a multilayer dielectric film, e.g., a ZAZ structure where Z and A mean ZrO₂ and Al₂O₃, respectively, in ZrO₂/Al₂O₃/ZrO₂, or a laminating layer having a plurality of Al₂O₃ and ZrO₂ layers alternately.

This structure aims to accomplish the desirable characteristic from the combination of zirconium oxide (ZrO₂) having high permittivity and aluminum oxide (Al₂O₃) having high thermostability instead of high permittivity.

For example, JP 2006-135339 A discloses an AZ, ZA, or ZAZ structure, or a method for forming a multilayer dielectric film alternately laminating a ZrO₂ thin film and an Al₂O₃ thin film.

The flat capacitor described as a first embodiment in FIG. 8 of WO 2009/090970 includes a lower electrode layer (83) including a first electrode layer (83a) made of a TiN film and a second electrode (83b) made of a TiSiN film of the amorphous conductive layer, a dielectric layer (84) including a first dielectric layer (84a) made of a SiN film, a second dielectric layer (84b) made of an STO film, and a third dielectric layer (84c) made of a SiN film, an upper electrode layer (85) including a third electrode layer (85a) made of a TiSiN film of the amorphous conductive layer and a fourth electrode layer (85b) made of a TiN film. In the configuration, the TiSiN film of the amorphous conductor, which constitutes the second electrode layer (83b) and the third electrode layer (85a), is explained as being able to be deposited by a sputtering or heated CVD (Chemical Vapor Deposition) method. The heated CVD method is described to be desirable with a deposition temperature of approximately 520° C. using sources of TiCl₄, NH₃ and SiH₄. However, the sputtering method may be used for a flat capacitor with no issue, but may not be applied for a three-dimensional capacitor because of inferior step coverage. Furthermore, because the heated CVD method uses three kinds of source gases, uniformity in a film thickness or composite ratio may hardly be achieved as it goes down to the bottom of the deep holes in the three-dimensional structure.

Further, WO 2009/090979 has a silicon nitride film (SiN film) on and under an STO film which is a dielectric film having a high permittivity, and states that it would be good if the film thickness of each SiN film is 2 nm. SiN film may maintain the flatness of the surface because it is amorphous, and is thus thought to prohibit an increase in leakage current of a capacitive insulation film made of SiN film/STO film/SiN film. However, the permittivity of SiN is twice as high as that of silicon oxide at best, and thus the whole capacitive insulation film would not substantially take advantage of the effect of using an STO film having a high permittivity. In other words, for a capacitive insulation film composed of an SiN film having 2 nm thick/an STO film having 4 nm thick/an SiN film having 2 nm thick, as described in this document, an EOT (Equivalent Oxide Thickness: a film thickness converted using the permittivity of SiO, i.e., 4) is 1 nm+0.16 nm+1 nm, i.e., 2.16 nm, given that SiN has a permittivity of 8 and STO has a permittivity of 100. When the STO film is a single layer film, a large capacity may be accomplished due to its EOT of 0.16 nm. However, once SiN films with a total physical thickness of 4 nm are laminated on and under the STO film, the EOT becomes 13.5 times larger and the capacity becomes smaller by one order or more. In this capacitor structure, it is assumed that leakage current may be prohibited and reliability may be ensured, but a large capacity may not be obtained. Furthermore, the structure may not apply to a high integrated memory device having F value of 40 nm or less, which requires an EOT value of less than 0.9 nm.

A flat capacitor described as a second embodiment in FIG. 12 of WO 2009/090979 is identical to the structure of the first embodiment above except that there has not the first dielectric layer (84a: SiN) and the third dielectric layer (84c: SiN). That is, the second dielectric layer (84b: STO) is in contact with the third electrode layer (85a) made of an amorphous conductor of TiSiN. In this configuration, an EOT is smaller and a large capacity may be obtained because the STO film, which has a high permittivity, only constitutes the dielectric film (84). However, as stated above, the temperature required to produce TiSiN, which is an amorphous conductor, by a CVD is 520° C., which corresponds to a crystallization annealing temperature of an STO film, i.e., 400° C. to 600° C., as described in paragraph [0036] of this document. Therefore, this means that the STO film is crystallized at a preliminary heating step shortly before the third electrode layer (85a) is formed, and that the third electrode (85a) is formed on the crystallized STO.

As paragraph [0038] of this document clearly mentions that the surface morphology of an STO film may deteriorate, the problem of an increase in leakage current would arise. In the above first embodiment of this document, despite a deterioration of the surface morphology of the STO film, leakage current does not increase owing to the SiN film formed to improve the surface morphology and to an electrode formed on the SiN film. However, in the second embodiment, an electrode is formed directly on the STO film having a deteriorated surface morphology, and an increase in leakage current may not thus be avoided.

A ZAZ structure described in JP 2006-135339 is a superior capacitor structure which may suppress leakage current.

However, if the allowable leakage current density of a DRAM capacitor is set as 1E−7 (A/cm²) under a bias of 1 V, an EOT of a capacitor having a ZAZ structure has been limited to 0.9 nm.

As stated above, for a miniaturized DRAM having a minimum feature size (F value) of 40 nm or lower, there has been demand for increase the capacity per unit area of an electrode by decreasing the EOT below 0.9 nm.

One of the reasons why an EOT may not be smaller in a ZAZ structure is that aluminum oxide (Al₂O₃) having a low relative permittivity (∈=8.9) is used to a portion of a dielectric film. But, until now, a capacitor using a single layer of crystallized zirconium oxide has large leakage current although it may have a small EOT. Therefore, it is difficult to commercialize such a capacitor.

### SUMMARY

To solve the problems above, the present invention provides a semiconductor device having a three-dimensional capacitor and a method for manufacturing the device. The capacitor has an MIM structure using a metal or metallic compound in upper and lower electrodes and utilizes a dielectric film having a high permittivity for a capacitive insulation film.

Specifically, one embodiment of the invention provides a method for manufacturing a semiconductor device including a formation of a capacitor, wherein the formation of the capacitor comprises at least:

forming a lower electrode comprising titanium nitride on a semiconductor substrate,

forming a dielectric film comprising zirconium oxide, and

forming an upper electrode comprising titanium nitride on said dielectric film,

wherein at least the uppermost layer of said dielectric film is formed by an atomic layer deposition (ALD) method, and

wherein said formation of the capacitor further comprises, between said step of forming the dielectric film and said step of forming the upper electrode, forming a first protective film on said uppermost layer of said dielectric film without exceeding the film forming temperature of said ALD method over 70° C.

According to the present invention, since the uppermost layer of a dielectric film provided between a lower electrode and an upper electrode for a capacitor is formed at least by an atomic layer deposition (ALD) method and a protective film is formed on said dielectric film without exceeding the film forming temperature of the ALD method over 70° C., i.e., without imparting damages such as cracks to the dielectric film, the dielectric film can be free from damages such as cracks even if a heat treatment on film forming of the upper electrode, which has been formed on the protective film, is performed so that the capacitor can thus be formed with an excellent leakage current characteristic.

### BRIEF DESCRIPTION OF DRAWINGS

The above features and advantages of the present invention will be more apparent from the following description of certain preferred embodiments taken in conjunction with the accompanying drawings, in which:

FIG. 1 is a schematic, cross-sectional view of a capacitor structure in the related art.

FIG. 2 is a graph illustrating the characteristic of leakage current in the capacitor of FIG. 1.

FIG. 3 is a graph illustrating the dependence of the leakage current characteristic of the capacitor of FIG. 1 on a dielectric film thickness.

FIG. 4 is a schematic image view of crystalline states of zirconium oxide depending on the film thicknesses of 4 nm (a), 6 nm (b), and 8 nm (c), respectively.

FIG. 5 is a schematic view explaining why a crack generated during the formation of an upper electrode causes an increase in leakage current. FIG. 5(a) represents a case where an upper electrode is formed with a PVD-TiN at a room temperature, FIG. 5(b) represents a case where an upper electrode is formed with a PVD-TiN at a room temperature after a dielectric film is heat-treated, and FIG. 5(c) represents a case where an upper electrode is formed with a CVD-TiN.

FIG. 6 is a schematic, cross-sectional view of a flat capacitor for evaluating a capacitor structure according to one embodiment of the invention.

FIG. 7 is a cross-sectional view illustrating processes for manufacturing the capacitor structure of FIG. 6.

FIG. 8 is a graph illustrating a leakage current characteristic of the capacitor structure depicted in FIG. 6.

FIG. 9 is a graph illustrating a leakage current characteristic under the effect of a first protective film in the capacitor structure depicted in FIG. 6.

FIG. 10 is a graph illustrating the dependence of the leakage current characteristic of the capacitor structure depicted in FIG. 6 on the dielectric film thickness.

FIG. 11 is a graph illustrating the effect of the thickness of the first protective film on the leakage current characteristic in the capacitor structure depicted in FIG. 6.

FIG. 12 is a view illustrating the relation between an EOT and a thickness of the combination of a ZrO film and a TiO film.

FIG. 13 is a schematic view of a flat capacitor for evaluating a capacitor structure according to another embodiment of the present invention.

FIG. 14 is a graph illustrating the dependence of a leakage current characteristic of the capacitor structure of FIG. 13 on the thickness of a second protective film.

FIG. 15 is a graph illustrating a leakage current characteristic for describing the effect of the first protective film as a protective film in the capacitor structure of FIG. 13.

FIG. 16 is a view illustrating the steps of sequentially forming a second protective film, a dielectric film, and a first protective film in the same film formation apparatus with respect to the capacitor structure of FIG. 13.

FIG. 17 is a graph illustrating a leakage current characteristic for a capacitor formed sequentially by the steps of FIG. 16.

FIG. 18(a) is a schematic, cross-sectional view describing a method of forming a capacitor structure according to the other embodiment of the present invention, and FIG. 18(b) is a flowchart of the forming process thereof.

FIG. 19 is a graph illustrating a leakage current characteristic of a capacitor structure fabricated by the method of FIG. 18.

FIG. 20 is a graph showing the effect of a post annealing on a leakage current characteristic.

FIG. 21 is a graph illustrating the relation between an EOT and a leakage current at +1 V with respect to several capacitors.

FIG. 22 is a schematic, cross-sectional view illustrating the whole structure of DRAM as a semiconductor memory device according to the present invention.

FIG. 23 is a plane view of FIG. 22 taken along line X-X.

FIGS. 24(a) to 24(i) are cross-sectional views illustrating a manufacturing process for the capacitor of FIG. 22

### DETAILED DESCRIPTION OF REFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purpose.

Considering the applicability to a three-dimensional structure, the easiness of forming a film, and a high permittivity, a zirconium oxide (ZrO₂: hereinafter “ZrO”) film is promising as a dielectric film of a capacitor. However, as described in the Background, a single layer ZrO film is inferior for suppressing leakage current.

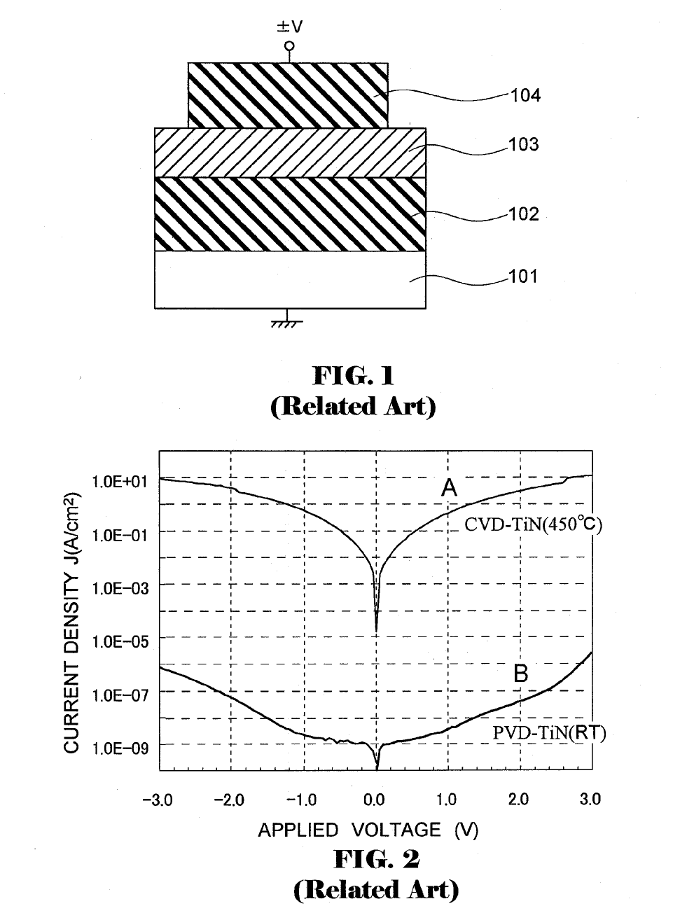

Exemplary experiments performed by the inventors here as to the leakage current characteristic of a single layer ZrO film are described with reference to FIGS. 1 to 5.

### (Experiment 1)

FIG. 1 shows the structure of a flat capacitor including, on semiconductor substrate 101, which is mono-crystalline silicon, lower electrode 102 made of a titanium nitride film (TiN film), upper electrode 104 made of a TiN film in the same way, and dielectric film 103 composed of a ZrO film sandwiched between the upper and lower electrodes.

Lower electrode 102 made of a TiN film has been formed using a chemical vapor deposition (CVD) method with reaction gases of titanium tetrachloride (TiCl₄) and ammonia (NH₃) in consideration of the application thereof to a three-dimensional structure. The deposition temperature was 450° C., and the thickness of the film was 10 nm. Hereinafter, a TiN film formed by a CVD method is referred to as a CVD-TiN film. The CVD-TiN film is a conductor in a polycrystalline state.

The ZrO film, which is to be dielectric film 103, has been formed using an atomic layer deposition (ALD) method with a reaction gas of ozone (O₃) and a Zr precursor of TEMAZ, i.e., tetrakis(ethylmethylamino) zirconium:Zr[N(CH₃)CH₂CH₃]₄, which is an organometallic complex. The temperature of forming the film was 250° C. and the film thickness was 6 nm. Dielectric film 103 is formed by repeating a fundamental sequence until a desired film thickness is obtained, the sequence including the steps of introducing the Zr precursor into a reaction chamber in which a semiconductor substrate is installed and adsorbing the Zr precursor on the surface of the lower electrode as one atomic layer, nitrogen-purging the remaining precursor in a gas phase, introducing ozone and oxidizing the adsorbed precursor, and nitrogen-purging the remaining ozone in a gas phase.

Upper electrode 104 made of a TiN film has been formed using a mask sputtering method with a known area. The mask sputtering method is to set a flat mask on the top surface of the ZrO film, to deposit a TiN film (hereinafter referred to as “PVD-TiN film”) thereon by a sputtering method, and to form an upper electrode in dot shape. The depositing temperature was room temperature, and the film thickness was 10 nm.

The curve indicated as Reference B in FIG. 2 illustrates the characteristic of leakage current when a voltage between −3 V and +3 V is applied to upper electrode 104 in the capacitor structure explained above. It is notified that +2.3 V and −2.2 V became the voltages applied to meet the index of current density, i.e., 1 E−7 (A/cm²). The above capacitor shows the good leakage current characteristic having a sufficient margin in that the leakage current standard, which is allowable for use as a semiconductor device, is equal to 1 V or more in both positive and negative values at the current density level.

The curve indicated as Reference A in FIG. 2 shows a result where the upper electrode uses a CVD-TiN film as does the lower electrode instead of a PVD-TiN film. As clearly depicted in the figure, the leakage current increases by seven exponents under the structure of the upper electrode made of a CVD-TiN film compared to the structure of the upper electrode made of a PVD-TiN film. The capacitor in this case makes it difficult to store information therein, and cannot be in use.

For application to a three-dimensional capacitor, as stated above, the upper electrode, as well as the lower electrode, should be formed by a CVD method, which ensures good step coverage. However, the characteristic indicated by Reference A has a substantially large amount of leakage current, thereby failing to make a semiconductor device in use.

The inventors here have examined the difference in the methods of the upper electrode, i.e., several conditions in sputtering and CVD methods, to find what condition influences the leakage current in the ZrO film, which forms a dielectric film, to change severely. As a result, the primary causes of severely changing leakage current are assumed as the temperature of forming a film. That is, the primary cause is thought to be the fact that the sputtering method has been performed at room temperature, while the CVD method has been performed at 450° C.

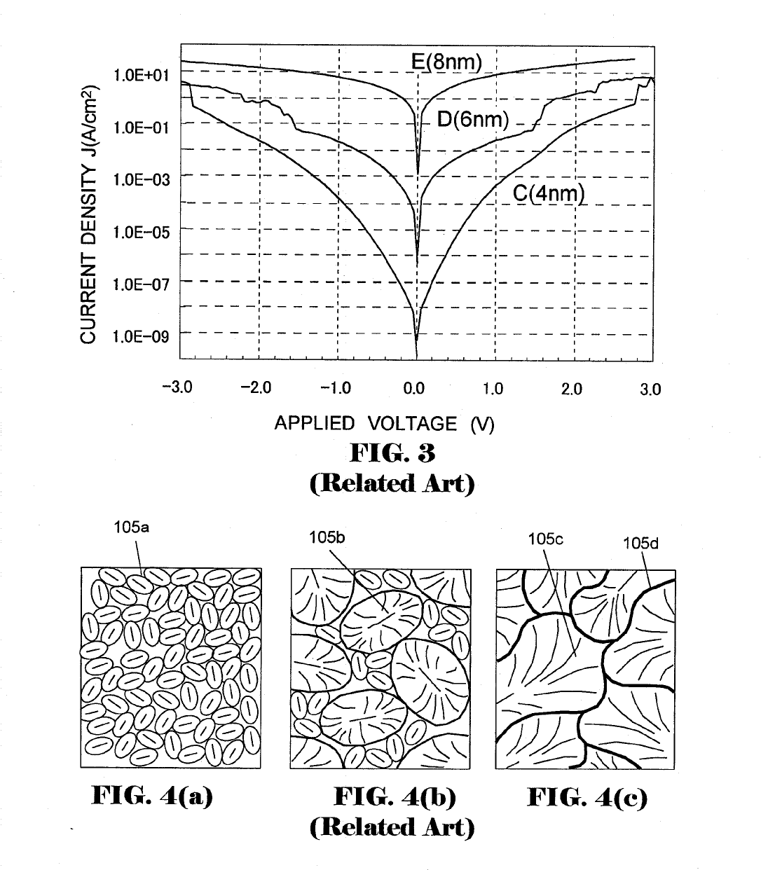

FIG. 3 shows leakage current characteristics of the capacitor structure of FIG. 1 where, as one example of evaluation results, a ZrO film is formed in a thickness of 4 nm (Reference A), 6 nm (Reference D), or 8 nm (Reference E), and a CVD-TiN film formed at a deposition temperature of 450° C. is used as an upper electrode. Typically, with respect to an amorphous dielectric film such as an aluminum oxide film, a silicon nitride film or a silicon oxide film, a thicker film causes a lower density of an electric field within the film, thereby reducing leakage current. However, a ZrO film shown in FIG. 3 does not show such a tendency, and has the least leakage current with respect to the thinnest thickness of 4 nm (Reference C). The leakage current intends to increase as the film thickness becomes thicker from 6 nm (Reference D) to 8 nm (Reference E).

The result in FIG. 3 is thought to strongly show an association with the crystallization process of a ZrO film. Thus, the inventors here obtained the following findings from the measurement of X-ray diffraction peak intensity and from the observation of an image from a transmission electron microscope.

A ZrO film is in a microcrystalline state at a stage shortly after the film formation at 250° C., but is in a polycrystalline state at a stage where a CVD-TiN film has been formed. When a ZrO film in a microcrystalline state is heat treated at a temperature higher than that of the film formation, a secondary growth of crystal grains arises. The secondary growth of crystal grains depends on a film thickness, and thus, under the same condition of heat treatment, a thicker film leads a polycrystalline structure with a larger grain size. As described herein, a “secondary growth of crystal grains” means that the rearrangement of constituent atoms by, for example, a heat treatment after film formation, and the change into larger crystal grains by the reformation of grain boundary, while a primary growth of crystal grains means the growth of crystals during film formation.

FIG. 4 shows schematic images of crystal grains observed by a transmission electron microscope. FIGS. 4(a) to 4(c) represent in cases of the thicknesses of a ZrO film being 4 nm, 6 nm, and 8 nm, respectively, and show images after heat treatment at 450° C., which is a deposition temperature of a CVD-TiN film. All images clearly show crystal grains. For a film thickness of 4 nm (FIG. 4(a)), there is a growth of crystal grains, but a polycrystalline state composed of a group of small crystal grains 105a. For a film thickness of 6 nm (FIG. 4(b)), there shows a polycrystalline state having a mixture of medium crystal grains 105b and small crystal grains 105a. For a film thickness of 8 nm (FIG. 4(c)), there shows a polycrystalline state having obvious grain boundary 105d (bold lines) with a group of larger crystal grains 105c than medium crystal grains 105b while small crystal grains 105a disappear. In the polycrystalline state of FIG. 4(c), the rearrangement of atoms occurred with the progress of crystallization and the volume contraction by the volatilization of impurities within the film are thought to cause cracks in the grain boundary as illustrated with bold lines.

A microcrystalline state is a state where a small peak caused by crystals is observed by an X-ray diffraction, but obvious crystal grains are not observed from a transmission electron microscope image. This is different from a state where crystal grains are obviously observed in a transmission electron microscope image as shown in each image in FIG. 4.

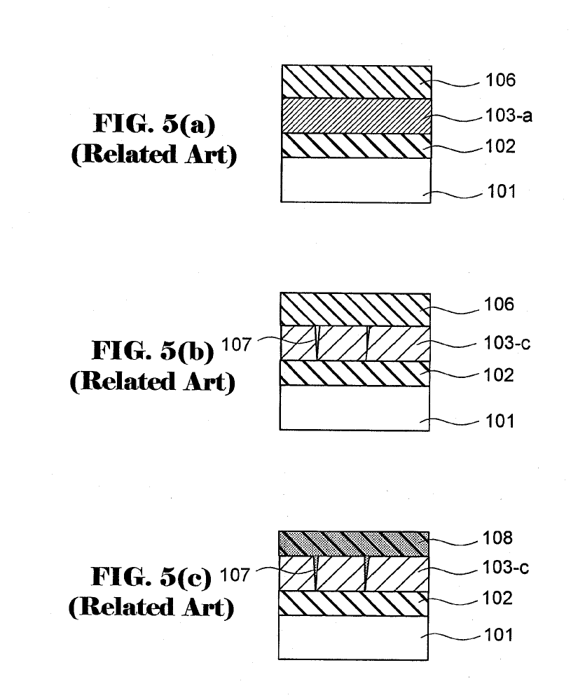

FIG. 5 is a schematic view to explain the reason why a crack occurring at the time of the upper electrode formation brings the increase of the leakage current.

FIG. 5(a) shows a structure in which microcrystalline ZrO (hereinafter referred to as “mc-ZrO”) film 103-a as dielectric film 103 is formed by an ALD method on lower electrode 102 made of a TiN film, and then PVD-TiN film 106 is formed as an upper electrode at room temperature. In this case, mc-ZrO film 103-a is not heat treated at a temperature above the film forming temperature thereof, and thus a secondary growth of crystal grains does not occur and cracks are not caused. As a result, leakage current has the characteristic of Reference B in FIG. 2.

FIG. 5(b) shows a structure in FIG. 5(a), in which mc-ZrO film 103-a is deliberately heat-treated at approximately 450° C. to promote a secondary growth of crystal grains so as to change into a dielectric film made of polycrystalline ZrO (hereinafter referred to as “pc-ZrO”) film 103-c having cracks 107, and under this circumstance, PVD-TiN film 106 is formed as an upper electrode at room temperature. Because PVD-TiN film 106 has inferior step coverage, PVD-TiN film 106 cannot be filled with cracks 107. Therefore, the leakage current in this case is substantially identical to the characteristic to Reference B of FIG. 2.

FIG. 5(c) is a structure, in which, after mc-ZrO film 103-a as a dielectric film is formed on lower electrode 102 made of a TiN film by an ALD method, CVD-TiN film 108 is deposited on the dielectric film as an upper electrode at 450° C. In this case, mc-ZrO film 103-a also changes into pc-ZrO film 103-c, and cracks 107 caused by the secondary growth of crystal grains arise. Furthermore, because the CVD method has good step coverage, which is applicable to a three-dimensional structure of an electrode, CVD-TiN film 108 also enters, and is formed at, the inside of cracks 17. Therefore, the leakage current in this case has a deteriorating characteristic as Reference A of FIG. 2.

A CVD film forming apparatus, not limited to a formation of a TiN film, is in a preliminary heating state for a certain period of time until a predetermined temperature is stably reached, i.e., until a film forming process begins, because the predetermined temperature is not quickly reached when a substrate is installed in the film forming apparatus. Therefore, during this preliminary heating state, cracks are caused by the growth of crystal grains when heating mc-ZrO film 103-a. Because CVD-TiN film 108 subsequently begins to be formed after the cracks arise, the cracks are filled with CVD-TiN film 108 in a CVD method having good step coverage. As a result, in the bottom of cracks 107, lower electrode 102 and CVD-TiN film 108 as the upper electrode face each other with thin dielectric film interposed therebetween and therefore, the leakage current increases. In an extreme case, it causes a short-circuit state. In a case where a ZrO film has a thin film thickness and a secondary growth of crystal grains are delayed, cracks are also caused locally, which is thought to be lead an increase in leakage current. Even though there is no obvious crack, the surface atomic migration occurred with the secondary growth of crystal grains increases the unevenness of the surface, which creates a portion of the film having a relatively thin thickness and thus increases leakage current. The extreme deterioration of a leakage current characteristic by seven exponents, as shown in FIG. 2, is thought to be caused by the occurrence of cracks.

As described above, in FIG. 2, the reason why the leakage current is small when a PVD-TiN film is used for an upper electrode, and increases when a CVD-TiN film is used with heat treatment, is thought to be caused by the fact that the ZrO film is in a polycrystalline state and causes cracks in grain boundaries at a preliminary heating stage at 450° C. shortly before the formation of a CVD-TiN film, and that a CVD-TiN film with good step coverage is formed within the cracks. If a PVD-TiN film is used for an upper electrode, influence due to cracks may be avoided, but the PVD-TiN film is not applicable to a three-dimensional structure due to its inferior step coverage.

As stated above, it is assumed that, in order to prevent the generation of cracks with the secondary growth of crystal grains of a ZrO film, it is better to cover the surface of the ZrO film with a protective film at a temperature at which a secondary growth of crystal grains of a ZrO film is not allowed, and then to form a CVD-TiN film as an upper electrode. Therefore, the inventors here found that a titanium oxide (TiOx where x is a positive real number of 2 or less) film is promising as a result of evaluation of several materials for a protective film. Hereinafter, it is explained a capacitor structure according to one embodiment of the present invention, wherein a TiO film as a protective film is formed on a ZrO film as a dielectric film, and a CVD-TiN film is formed thereon as an upper electrode.

### (Experiment 2)

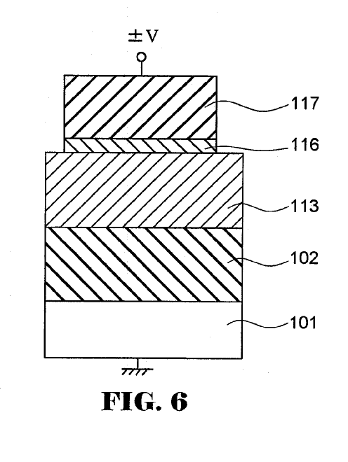

FIG. 6 illustrates a capacitor structure including, on mono-crystalline silicon semiconductor substrate 101, lower electrode 102 made of a CVD-TiN film, dielectric film 113 made of pc-ZrO film 113-c, first protective film 116 made of polycrystalline TiO (hereinafter referred to as “pc-TiO”) film 116-c, and upper electrode 117 made of a CVD-TiN film. The capacitor structure in this experiment is not three-dimensional semiconductor memory as explained above, and is constructed as a flat capacitor to achieve an easily manufacturable structure for evaluating its characteristics.

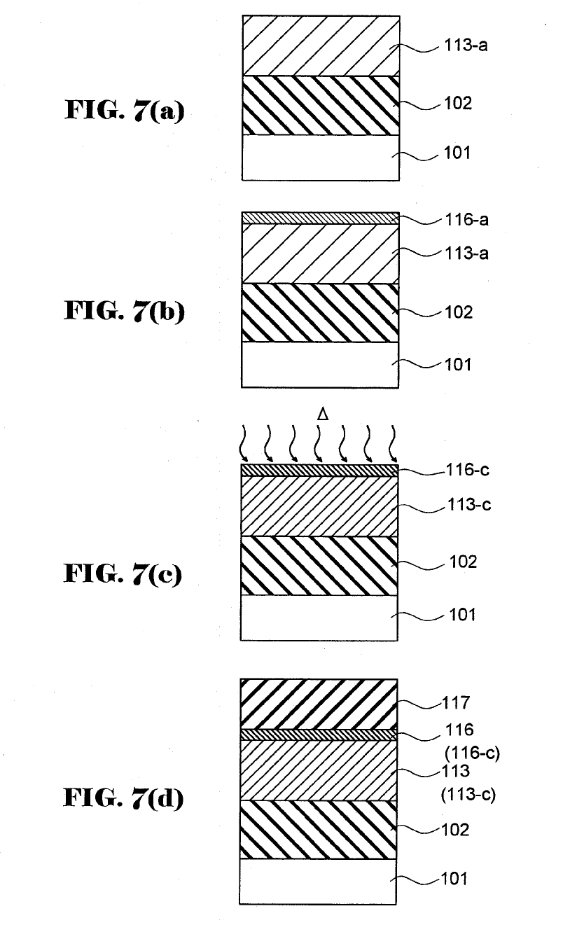

A method for manufacturing the capacitor depicted in FIG. 6 is now explained in reference to FIG. 7.

First, on semiconductor substrate 101, a CVD-TiN film, which is to be lower electrode 102, is formed by a CVD method with reaction gases of TiCl₄ and NH₃, as in Experiment 1, in consideration of its application to a three-dimensional structure. The film forming temperature can be 380° C. to 600° C., and preferably 450° C. in this experiment. This TiN film has a thickness of 10 nm, and is in a polycrystalline state at the film forming stage (see FIG. 7(a)).

Then, a ZrO film, which is to be dielectric film 113, is formed, as in Experiment 1, to have a thickness of 6 nm by an ALD method using TEMAZ and ozone at 250° C. The ZrO film formed by the ALD method is in a microcrystalline state, i.e., mc-ZrO film 113-a (see FIG. 7(a)). TEMAZ was used for a Zr precursor here, but the precursor is not limited to TEMAZ. Ozone was used as a reaction gas, but the reaction gas is not limited to ozone. For example, H₂O (water vapor) can be used as the reaction gas.

It is preferable to set a film forming temperature within the range from 210° C. to 280° C. No reaction will take place below 210° C., and a decomposition reaction of a Zr precursor will occur in a gas phase if a temperature is above 280° C. In both cases, a film is difficult to be formed.

Then, a TiO film is formed for first protective film 116. The first protective film is formed to have a thickness of 1 nm by an ALD method at 250° C. with a reaction gas of ozone and a Ti precursor of TTIP (titanium tetra-isopropoxide: Ti(OCHMe₂)₄) (see FIG. 7(b)). Specifically, the film forming process by an ALD method includes a fundamental sequence of (1) introducing the Ti precursor in a reaction chamber where a semiconductor substrate is installed and then adsorbing the Ti precursor on the surface of mc-ZrO film 113-a, which is to be dielectric film 113, as an atomic layer level, (2) nitrogen-purging the remaining Ti precursor in a gas phase, (3) introducing ozone and oxidizing the adsorbed Ti precursor, and (4) nitrogen-purging the remaining ozone in a gas phase. The film formation was developed by repeating the fundamental sequence of the above four steps until the film has a thickness of 1 nm. A film formation by an ALD method is desirable in that it has a better step coverage and is easily applicable to a three-dimensional structure because the formation uses a surface adsorption reaction. A TiO film at the stage of film formation by an ALD method is in an amorphous state (first amorphous TiO (hereinafter referred to as “a-TiO”) film 116-a). Here, TTIP was used for a Ti precursor, but the Ti precursor is not limited to TTIP. TiMCTA (methylcyclopentadienyl tris(dimethylamino) titanum: (MeCp) Ti(NMe₂)₃) can be used for the Ti precursor. Ozone was used for a reaction gas, but the reaction gas is not limited to ozone, and can use, for example, H₂O. The film formation temperature was set 250° C., but can be preferably within the range from 210° C. to 280° C. No reaction will take place below 210° C., and, if a temperature is above 280° C., a decomposition reaction will occur in a gas phase so as to prohibit an ALD film formation.

Then, a CVD-TiN film is formed for upper electrode 117. Like the case of lower electrode 102, the CVD-TiN film for upper electrode 111 was formed to have a thickness of 10 nm by a CVD method at 380° C. to 600° C., preferably at 450° C., in consideration of its application to a three-dimensional structure. First of all, semiconductor substrate 101 is installed in a CVD film forming apparatus, and is left alone until a temperature becomes stable. At the stage of a stable temperature, mc-ZrO film 113-a and a-TiO film 116-a are heat treated so that mc-ZrO film 113-a changes into pc-ZrO film 113-c and a-TiO film 116-a changes into pc-TiO film 116-c. At the stage of a stable temperature, a CVD-TiN film is formed with a thickness of 10 nm for upper electrode 117. The CVD-TiN film is in a polycrystalline state at the film forming stage (see FIG. 7(d)). The TiO film formed as the first protective film is in an amorphous state, which is independent on the film thickness at the film formation stage, but has dependence on the film thickness at the stage of changing into a polycrystalline state by heat treatment. As described later, the a-TiO film with a thickness of less than 1 nm remains an amorphous state without changing into a polycrystalline state. In contrast, the a-TiO film with a thickness of 1 nm or more changes from an amorphous state to a polycrystalline state by heat treatment. The pc-TiO film functions as a conductor. In this experiment, because first protective film 116 is formed with 1 nm thickness, a-TiO film 116-a changes into pc-TiO film 116-c after forming the upper electrode accompanied with heat treatment.

After upper electrode 117 was formed, a mask material (not shown) with a known area has been formed on upper electrode 117, and upper electrode 117 was etching-removed using the mask material as a mask. As a result, a capacitor structure was formed as shown in FIG. 6. The portion of TiO film 116 that is exposed on a part devoid of the mask is also etched by this etching process.

In this experiment, because upper electrode 117 is formed at 450° C., dielectric film 113, which has been formed earlier, changes from mc-ZrO film 113-a to pc-ZrO film 113-c, and a-TiO film 116-a as first protective film 116 may change into pc-TiO film 116-c depending on its film thickness. As a result, the capacitor in this experiment includes lower electrode 102 made of the CVD-TiN film, dielectric film 113 made of pc-ZrO film 113-c, first protective film 116 made of pc-TiO film 116-c, and upper electrode 117 made of the CVD-TiN film. In other words, the capacitor includes lower electrode 102 connected to semiconductor substrate 101, dielectric film 113 covering lower electrode 102, first protective film 116 formed on dielectric film 113, and upper electrode 117 formed on first protective film 116. a-TiO film 116-a with 1 nm thickness in this experiment changes into pc-TiO film 116-c to function as a conductor, and thus plays a part of an upper electrode as well as a protective film.

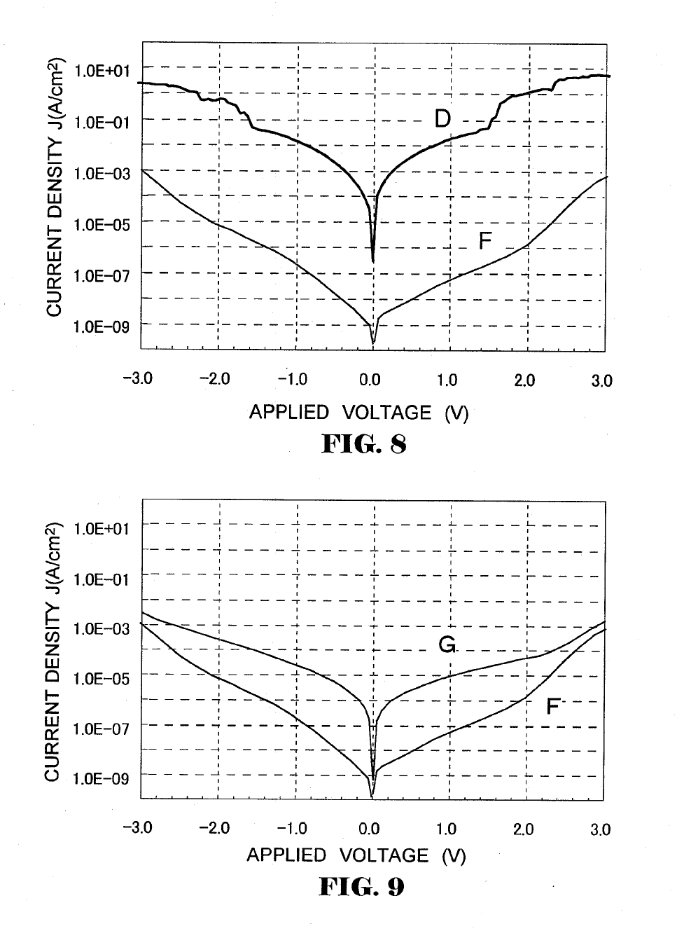

FIG. 8 illustrates the leakage current characteristic of the capacitor shown in FIG. 6. The horizontal axis indicates a voltage applied to upper electrode 117, and the vertical axis shows a leakage current value per unit area, which corresponds to an applied voltage. The characteristic identified by Reference D is a leakage current characteristic when a ZrO film as depicted in FIG. 3 has a thickness of 6 nm, as an example of a capacitor having no first protective film. Reference F illustrates a leakage current characteristic when the capacitor includes first protective film 116 made of a TiO film with a thickness of 1 nm. When a voltage of +1 V is applied, the leakage current without first protective film 116 (Reference D) is 2 E−2 (A/cm²), and the leakage current with first protective film 116 (Reference F) is 7 E−8 (A/cm²). As specified from the comparison in FIG. 8, a capacitor with first protective film 116 made of a TiO film with a thickness of 1 nm decreases the leakage current by five exponents, compared to one without first protective film 116 (Reference D), and shows dramatic improvement. The EOT of 0.70 nm was obtained for a capacitor represented by Reference F. The EOT is calculated by a formula, EOT=∈0×∈r×S/C, where C is a capacity obtained from the capacity-voltage characteristic, ∈r is a relative permittivity of silicon oxide of 3.85, ∈0 is a permittivity of vacuum, and S is the area of the upper electrode.

The result above assumes that, at the process of forming upper electrode 117 at 450° C., first protective film 116 functions as a protective film for effectively preventing the generation of cracks during the crystallization of mc-ZrO film 113-a which is to be dielectric film 113. To prove this assumption, the leakage current characteristic is examined when the dielectric film made of mc-ZrO film 113-a is heat treated before first protective film 116 is formed. Like the method for forming a capacitor depicted in FIG. 7, mc-ZrO film 113-a with 6 nm thickness is formed as dielectric film 113 on lower electrode 102, and then the film is heat treated for 10 minutes at 400° C. under nitrogen atmosphere. At the time of heat treatment, mc-ZrO film 113-a changes into pc-ZrO film 113-c. After that, a-TiO film 116-a with a thickness of 1 nm is formed on the heat-treated dielectric film 113 by an ALD method at 250° C. Then, upper electrode 117 made of a CVD-TiN film with 10 nm thickness is formed by a CVD method at 450° C., and a capacitor is fabricated by forming an electrode pattern as in FIG. 6.

The leakage current characteristic of this capacitor is shown as Reference G in FIG. 9. Reference F in this figure is identical to Reference F in FIG. 8. As clearly depicted in FIG. 9, the leakage current increases when mc-ZrO film 113-a for the dielectric film 113 is heat treated before a-TiO film 116-a is formed. Because dielectric film 113 is heat treated at 400° C. in this case, the amount of the increase in leakage current in this case is smaller than that in the heat treatment at 450° C. as represented by Reference D in FIG. 8. However, it is impossible to maintain a level below 1E−7 (A/cm²), which is also a level of 1E−5 (A/cm²) at the applied voltage of +1 V. In the case of heat treatment at 450° C., it is assumed that the leakage current was increasing up to the level of Reference D of FIG. 8. Although a heat treatment at 400° C. is discussed here, a heat treatment at 350° C. also shows an increase in leakage current. However, no change in leakage current was acknowledged in a case of heat treatment at 300° C. In other words, the temperature of 300° C., which is higher by 50° C. than the film forming temperature (250° C.) of the ALD method for the dielectric film, has a small secondary growth of crystal grains, and is thus recognized as a level of no practical problem. Based on further examination, the inventors found that a practical problem would not cause at a temperature not higher by 70° C. than the film forming temperature of the ALD method for the dielectric film. Furthermore, it is required that there be no process of adding a temperature higher by 70° C. than the film forming temperature of the ALD method for the dielectric film, between the step of forming the dielectric film made of mc-ZrO film 113-a and the step of forming the first protective film made of a-TiO film 116-a.

As shown above, it is obvious that, if mc-ZrO film 113-a is heat treated at a temperature exceeding the film forming temperature over 70° C. before forming first protective film 116, first protective film 116 formed thereafter cannot function as a protective film. In other words, as shown in FIG. 5, after cracks are generated on dielectric film 113 by heat treatment, the material formed for a protective film cannot prohibit an increase in leakage current. That is, no practical capacitor can be obtained.

Therefore, to prevent an increase in leakage current, it is important to form a-TiO film 116-a, which is to be the first protective film, to cover the surface of mc-ZrO film 113-a at a temperature at which the secondary growth of crystal grains of mc-ZrO film 113-a, which is to be dielectric film 113, decreases, preferably at a temperature at which the secondary growth of crystal grains of the ZrO film does not substantially occur. If the film forming temperature of mc-ZrO film 113-a is identical to or higher than the film forming temperature of a-TiO film 116-a, no secondary growth of crystal grains arises.

The reason why the formation of first protective film 116 can prohibit an increase in leakage current is thought to be as follows. By forming a-TiO film 116-a as first protective film 116 without exceeding the film forming temperature of the ALD method for mc-ZrO film 113-a over 70° C., the surface of mc-ZrO film 113-a remains flat. The film forming temperature of a-TiO film 116-a as first protective film 116 causes less of the secondary growth of crystal grains, preferably is a temperature at which the secondary growth of crystal grains does not substantially occur. The formation of a-TiO film 116-a on the surface of mc-ZrO film 113-a can immobilize atoms or molecules constituting the surface of mc-ZrO film 113-a. Accordingly, in spite of subjecting to a heat treatment which leads cracks caused by the secondary growth of crystal grains of mc-ZrO film 113-a in the stage of the forming the upper electrode, the atoms or molecules constituting the surface cannot generally move, and thus not cause a change in the surface morphology. As a result, the surface of dielectric film 113 changing into a polycrystalline state remains flat. Therefore, when a heat treatment is performed to cause the secondary growth of crystal grains of mc-ZrO film 113-a after a-TiO film 116-a is formed, the secondary growth of crystal grains may occur to alleviate stress within dielectric film 113, but no crack is generated because the dielectric film maintains its surface flatness. Because the generation of cracks can be avoided, an event where leakage current increases due to the formation of an upper electrode in the cracks would not arise.

As explained above, in this experiment, it is required to cover the surface of the dielectric film with the first protective film formed by an ALD method at a temperature without exceeding the film forming temperature of the ALD method for the dielectric film over 70° C., preferably without performing heat treatment which would add a temperature higher by 70° C. than the film forming temperature of the ALD method for the dielectric film until the completion of forming the first protective film.

Then, for a structure depicted in FIG. 6, the leakage current characteristic is explained with reference to FIG. 10 when the thickness of a ZrO film for dielectric film 113 varies.

References H, F, I, J and K indicate cases where the thickness of ZrO film is 7 nm, 6 nm, 5.5 nm, 5 nm and 4.5 nm, respectively. Reference C is identical to Reference C in FIG. 2, and indicates a ZrO film thickness of 4 nm, i.e., when there does not exist a-TiO film 116-a, which functions as first protective film 116.

As expressed in FIG. 10, Reference K, which indicates the ZrO film thickness of 4.5 nm, represents the same leakage current characteristic as that with respect to the ZrO film thickness of 4 nm having no TiO film as first protective film 116. In other words, when a ZrO film has a film thickness of 4.5 nm or less, a-TiO film 116-a does not have an effect as a protective film. In contrast, where a ZrO film has a film thickness of 5 nm or more, the leakage current monotonously decreases as the film thickness increases, which proves that a-TiO film 116-a functions as a protective film for suppressing an increase in leakage current. When there is no first protective film 116, due to the generation of cracks in the ZrO film, the leakage current increases as the thickness of the ZrO film increases, which is the opposite to the result of FIG. 2. As such, first protective film 116 is found to effectively function as a protective film for prohibiting the generation of cracks in dielectric film 113.

The EOT of each sample in FIG. 10 represents 0.52 nm for the ZrO film thickness of 5 nm, 0.63 nm for the ZrO film thickness of 5.5 nm, 0.70 nm for the ZrO film thickness of 6 nm, and 0.83 nm for the ZrO film thickness of 7 nm. If the ZrO film is made to have a thick thickness as 8 nm, the leakage current decreases, but the EOT is 0.95 nm and fails the purpose of the present invention, which is to achieve an EOT of 0.90 nm or less. Therefore, the range of the thickness of the ZrO film, which would meet the purpose of the present invention, is 5 nm or more in consideration of improving a leakage current of the dielectric film, and is 7 nm or less in consideration of ensuring the EOT. In this experiment, when the film thickness is 5 nm or 5.5 nm, it does not satisfy a value of 1E−7 (A/cm²) or less under the bias of 1 V, which is a practical index for a semiconductor device. However, the film thickness of 5 nm or 5.5 nm also could meet a value of 1E−7 (A/cm²) or less by the application of a continuous film forming method, the application of a TiO film as a second protective film being in contact with the lower electrode, or the further densification of the dielectric film, as described later.

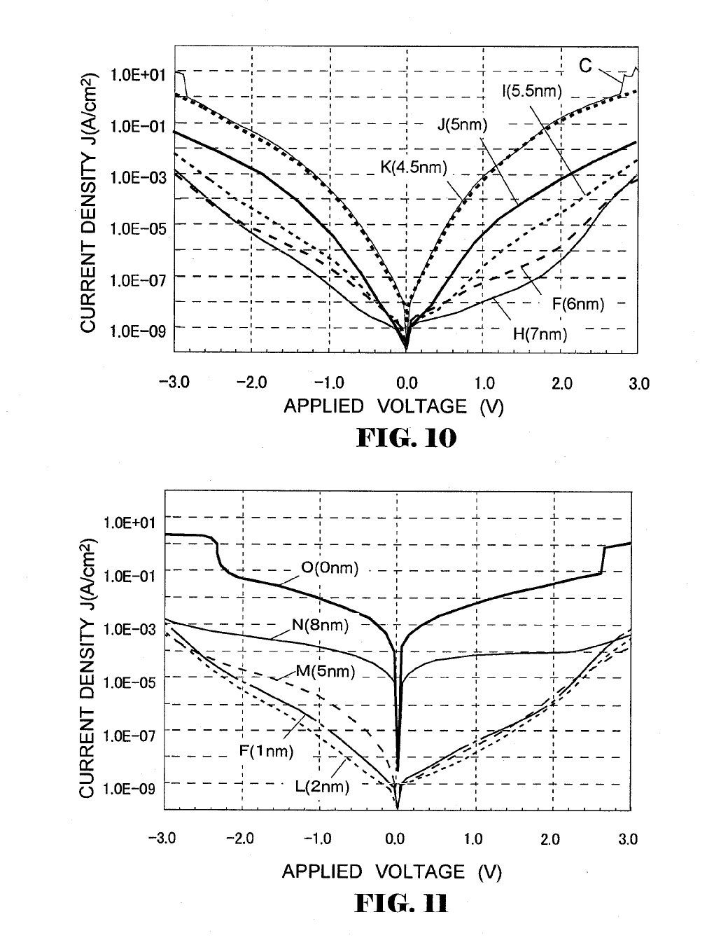

Now, FIG. 11 describes the effect of the thickness of a TiO film for first protective film 116 on the leakage current characteristic.

FIG. 11 shows the leakage current characteristic of a capacitor of FIG. 6 when a thickness of a TiO film used for first protective film 116 varies. Other structures of the capacitor are identical to those in FIG. 6. References O, N, M, F and L indicate the TiO film thickness of 0 nm, 8 nm, 5 nm, 1 nm, and 2 nm, respectively.

The results above prove the followings:
The leakage current is the largest when there is no TiO film (Reference O).
The leakage current is very large even when the TiO film has a thickness of 8 nm (Reference N).
When the TiO film has a thickness of 5 nm (Reference M) or less (References F and L), the leakage current sufficiently improves. In particular, the application of a positive voltage leads substantial effects. Among others, when the TiO film has a thickness of 1 to 2 nm (References F and L), the application of a negative voltage also has substantial effects. Based on the results above, it is found that when the TiO film for the first protective film is too thick, there is no effect of reducing leakage current, that there is an optimum range of the film thickness of the first protective film to reduce leakage current. Based on further examinations, the thickness of the first protective film falls within the range of 0.4 nm to 5.0 nm, preferably 0.4 nm to 2.0 nm, more preferably 0.4 nm to 1.0 nm, to suppress the generation of cracks in the dielectric film 113 and reduce leakage current. The thickness below 0.4 nm has no effect of preventing cracks in the dielectric film. The thickness above 5.0 nm causes cracks in the first protective film itself by heat treatment during the formation of the upper electrode, and thus the first protective film loses its function as a protective film. As the first protective film begins to have cracks, the dielectric film, which is right below the first protective film, is thought to have cracks at the same time.

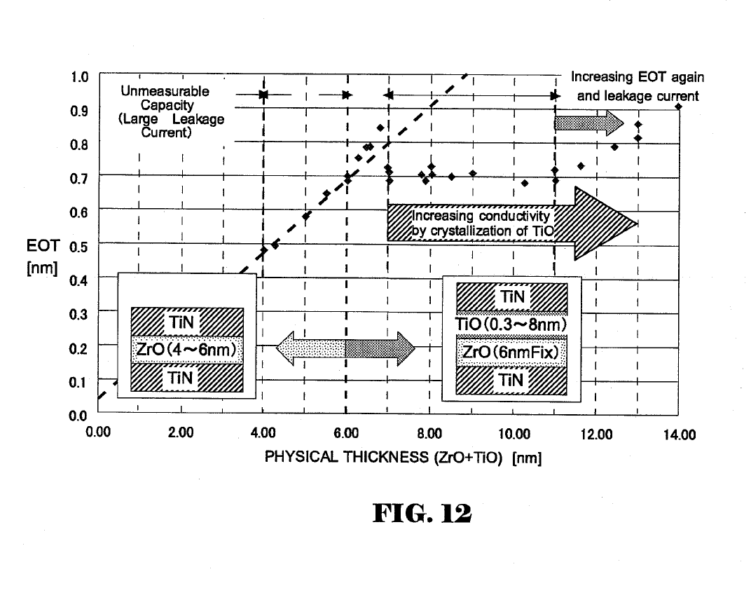

FIG. 12 is a view illustrating the result of the relation between an EOT and a combined thickness of the ZrO film for dielectric film 113 and the TiO film for first protective film 116. All data are associated with a heat treatment at 450° C. when a CVD-TiN film is formed as upper electrode 117.

FIG. 12 illustrates, in the horizontal axis, the combination of the physical film thickness of 4 to 6 nm made of a single layer film of a ZrO film and the physical film thickness of 6 to 14 nm made of a laminating layer film in which a TiO film with 0 to 8 nm thickness is formed on a ZrO film with 6 nm thickness. As depicted in the figure, a TiN/ZrO/TiN structure is within the physical thickness of 4 to 6 nm, and a TiN/TiO/ZrO/TiN structure is within a physical thickness of 6 to 14 (excluding 6) nm. A TiN/TiO/ZrO/TiN structure is a combination of a ZrO film for the dielectric film and a TiO film for the first protective film, and thus is simply called a TZ structure.

With respect to a film having a physical film thickness of less than 4 nm (a ZrO single layer film), a capacity may not be determined because of the increase in direct tunnel current. Therefore, an EOT does not appear. Within the range of a physical thickness between 4 and 6 nm, both inclusive, an EOT linearly increases as a ZrO film thickness increases. For example, an EOT is 0.48 nm for a film thickness of 4 nm, and an EOT is 0.69 nm for a film thickness of 6 nm. The relative permittivity obtained from the slope is approximately 38. Although a small EOT is obtained as above within the range of a physical thickness of 4 to 6 nm, it may not be used for a semiconductor device because its leakage current substantially increases in the single layer ZrO film.

When a TiO film is laminated on the ZrO film having 6 nm thickness, an EOT increases up to 0.85 nm as the thickness of the TiO film increases within the range of the TiO film thickness of less than 1 nm (the physical film thickness of 6 nm to less than 7 nm), but a EOT rapidly decreases as the TiO film thickness becomes 1 nm (the physical film thickness of 7 nm). An EOT remains substantially constant up until the range of the TiO film thickness of 5 nm (the physical film thickness of 11 nm), and the EOT is about 0.7 nm.

This result is thought to stem from the fact that, with the TiO film thickness of less than 1 nm, the TiO film still remains an amorphous state even after heat treatment at 450° C., and thus may function as a dielectric film, which causes an EOT to increase. Within the ranges of the TiO film thickness of 1 to 5 nm (the physical film thickness of 7 to 11 nm), the TiO film changes from an amorphous state to a polycrystalline state, and functions as a conductor, i.e., an electrode, by, for example, the oxygen deficiency occurred with crystallization. Therefore, an EOT is thought to remain stable. As such, within the range of the TiO film thickness of 1 to 5 nm, a small EOT (a large capacity) of 0.7 nm can be obtained stably and the leakage current illustrated in FIG. 11 can be in practical use. Therefore, that range is thought to be the range of a film thickness that can be applied to the TiO film, i.e., the first protective film in a semiconductor device according to this invention. Within the range of the TiO film thickness of less than 1 nm, although an EOT increases as the thickness of the TiO film increases, the EOT is still 0.9 nm or less, and thus cannot cause a problem. In the purpose of reducing leakage current, the TiO film with 0.4 nm or more thickness is found to have the effect of reducing leakage current. Accordingly, while maintaining the desired EOT, the film thickness of the first protective film is the range of 0.4 to 5.0 nm in order to reduce the leakage current of dielectric film 113. If the TiO film thickness is above 5 nm, an EOT tends to increase again. This finding seems to result from the fact that the TiO film, which functions as a conductor, partially suffers depletion in this range because the dependence of the capacity on the applied voltage increases. If the TiO film thickness is over 5 nm, an EOT, as well as leakage current, increases, and thus it may not be used for semiconductor memory. Furthermore, such a thick film may not be used as a protective film because of the cracks generated in the TiO film itself, as described above.

As stated above, when the first protective film made of a TiO film has a thickness of 1.0 to 5.0 nm, it changes into a polycrystalline state by heat treatment and thus functions as a conductor. Although the present experiment explains a method of crystallization by heat treatment during the formation of a TiN film for upper electrode 117, it is also effective to perform a heat treatment under reducing atmosphere before forming upper electrode 117 after forming first protective film 116 as a means to more actively promote the crystallization (see FIG. 7(c)). For example, if ammonia (NH₃) is used as reducing atmosphere, a heat treatment for 2 to 20 minutes at 380° C. to 460° C. makes it possible to reduce/remove organic impurities contained in a-TiO film 116-a and introduce oxygen deficiency into the TiO film, i.e., move to a low oxidization state (TiOₓ, where x is a positive real number less than 2), or to introduce nitrogen impurities, thereby eventually promoting crystallization. Therefore, it is effective to preliminarily change mc-ZrO film 113-a for dielectric film 113 and a-TiO film 116-a for first protective film 116 into a polycrystalline state (113-c, 116-c) by means of heat treatment under ammonia or hydrogen atmosphere before forming the TiN film for upper electrode 117. Because TiCl₄ and NH₃ are used as source gases for forming the TiN film which is to be upper electrode 117, a heat treatment in NH₃ atmosphere as a preliminary treatment just before forming the TiN film can be performed after installing a semiconductor substrate within a CVD film forming apparatus for a TiN film. In this case, the process can be simplified because a heat treatment can be performed under reducing atmosphere within the CVD film forming apparatus.

In this experiment, it has been explained an event where a ZrO film is used as a dielectric film for the purpose of reducing an EOT. However, in order to improve the leakage current characteristic, the first protective film can be applied to another dielectric film, which is in a microcrystalline state at the film forming stage where the grain boundaries are small and unobservable by a transmission electron microscope, and which may have a problem of cracks caused by the secondary growth of crystal grains during a film forming stage of a CVD-TiN film as an upper electrode.

### (Experiment 3)

As explained in Experiment 2, a CVD-TiN film, which is to be upper electrode 117 in a capacitor including a ZrO film for the dielectric film, is formed at a temperature of 380° C. to 600° C. In this case, to avoid the cracks occurred with the secondary growth of crystal grains of the ZrO film, it is required to cover the surface of the dielectric film made of mc-ZrO film 113-a with first protective film 116 made of a-TiO film 116-a before forming upper electrode 117.

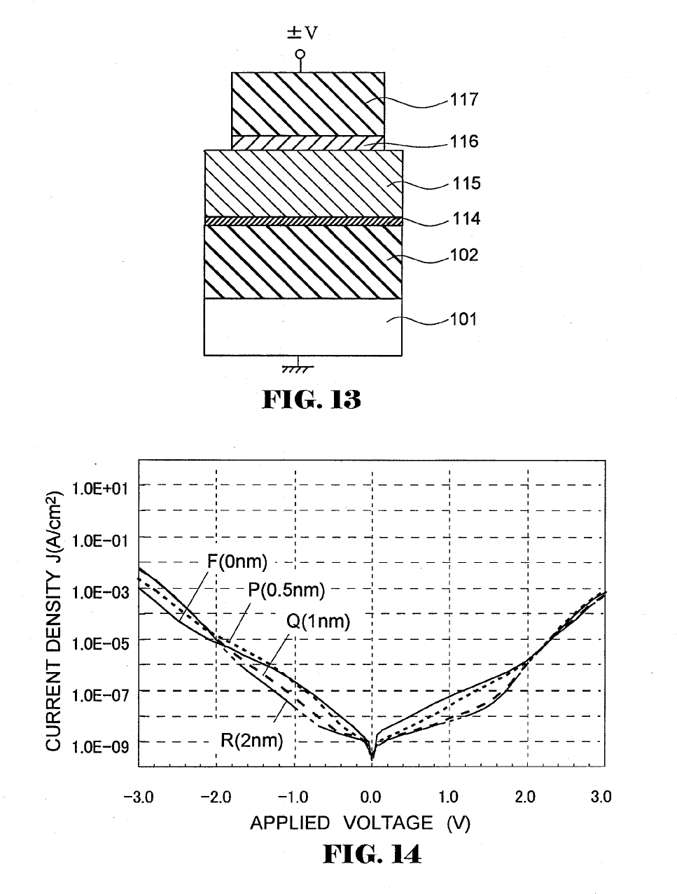

In this experiment, in order to improve further the leakage current characteristic, a capacitor structure in which, in addition to the aforementioned structure, a TiO film as a second protective film is formed between the lower electrode made of a TiN film and the ZrO film which is to be the dielectric film is described with reference to FIGS. 13 to 15. The capacitor according to this experiment has a stacked layer structure composed of a TiN film for upper electrode 117, a first TiO film for first protective film 116, a pc-ZrO film for dielectric film 115, a second TiO film for second protective film 114, and a TiN film for lower electrode 102. With respect to this structure of TiN film/TiO film/ZrO film/TiO film/TiN film, a first TiO film for the first protective film is combined with a ZrO film for the dielectric film and a second TiO film for the second protective film, and thus the structure is simply called a TZT structure.

FIG. 13 shows a capacitor structure in the present experiment.

The capacitor includes, on semiconductor substrate 101 of mono-crystalline silicon, lower electrode 102 made of a CVD-TiN film, second protective film 114 made of a TiO film, dielectric film 115 made of a pc-ZrO film, first protective film 116 made of a TiO film, and upper electrode 117 made of a CVD-TiN film.

In the capacitor in this experiment, the TiO film for second protective film 114 is amorphous under the condition of a film thickness less than 1.0 nm, and is polycrystalline under the condition of a film thickness of 1 nm or more, like first protective film 116 after heat treatment, as described later. Accordingly, FIG. 13 does not describe the distinctiveness in crystallinity.

It is now explained a method for manufacturing a capacitor depicted in FIG. 13.

First, a CVD-TiN film is formed as lower electrode 102 on semiconductor substrate 101. In consideration of the application to a three-dimensional structure, the film is formed by a CVD method with reaction gases of TiCl₄ and NH₃, as in Experiment 1. The film forming temperature can be set within the range of 380° C. to 600° C., and preferably 450° C. in this experiment. The thickness is 10 nm. This TiN film is in a polycrystalline state at the film forming stage.

Then, a TiO film is formed as second protective film 114. The film was formed by an ALD method at 250° C. with a Ti precursor of TTIP (titanium tetra-isopropoxide: Ti(OCHMe₂)₄) and a reaction gas of ozone so as to have a thickness of about 0.5 nm. Specifically, the film forming process by an ALD method includes a fundamental sequence of (1) introducing a Ti precursor in a reaction chamber where a semiconductor substrate is installed and then adsorbing the Ti precursor on the surface of lower electrode 102, as an atomic layer level, (2) nitrogen-purging the remaining Ti precursor in a gas phase, (3) introducing an ozone and oxidizing the adsorbed Ti precursor, and (4) nitrogen-purging the remaining ozone in a gas phase. The film formation was developed by repeating five times the fundamental sequence of the above four steps until the film has a thickness of 0.5 nm. A film formation by an ALD method is desirable in that it has a better step coverage and is easily applicable to a three-dimensional structure because the formation uses a surface adsorption reaction. The TiO film at the stage of the film formation by the ALD method is in an amorphous state. Here, TTIP was used as a Ti precursor, but the Ti precursor is not limited to TTIP. Ozone was used as a reaction gas, but the reaction gas is not limited to ozone. H₂O may be used for the reaction gas. The film formation temperature was set 250° C., but may be preferably within the range from 210° C. to 280° C. No reaction will take place below 210° C., and if a temperature is above 280° C., a decomposition reaction will occur in a gas phase so as to prohibit an ALD film formation. In this experiment, the TiO film for the second protective film 114 has a thickness of 0.5 nm, but may be desirable if it is within the range from 0.4 nm to 2 nm. If the thickness is below 0.4 nm, there is no effect of reducing leakage current. If the thickness is over 2 nm, the effect of reducing leakage current is saturated.

Then, a ZrO film for the dielectric film 115 is formed by an ALD method at 250° C. using TEMAZ and ozone so as to have a thickness of 6 nm, as in Experiment 1. The ZrO film formed by the ALD method is in a microcrystalline state. TEMAZ was used for a Zr precursor, but the Zr precursor is not limited to that. Ozone was used for a reaction gas, but the reaction gas is not limited to ozone. H₂O can be used as a reaction gas. The film forming temperature is preferably within 210° C. to 280° C. If the temperature is below 210° C., no reaction would arise. If the temperature is above 280° C., a decomposition reaction arises in a gas phase so as to prohibit an ALD film formation.

Then, a TiO film is formed as first protective film 116. The film is formed to have a thickness of 1 nm, as in the second protective film. This TiO film is also amorphous at the film forming stage. TTIP is used for a Ti precursor here, which is, however, not limited to TTIP. TiMCTA (methylcyclopentadienyl tris(dimethylamino) titanum: (MeCp)Ti(NMe₂)₃) can be used for the Ti precursor under the same condition. Because TiMCTA contains nitrogen, the TiO film will contain nitrogen at the film forming stage. Accordingly, crystallization can be promoted at a later heat treatment. In this experiment, the film formation of the TiO film and the film formation of the ZrO film are performed in different film forming apparatus.

Then, a CVD-TiN film, which is to be upper electrode 117, was formed. Like lower electrode 102, the CVD-TiN film for upper electrode 117 was formed to have a thickness of 10 nm by a CVD method at 380° C. to 600° C., preferably at 450° C., in consideration of the application to a three-dimensional structure, so as to have a thickness of 10 nm. This CVD-TiN film is in a polycrystalline state at the film forming stage. After that, as in Experiment 2, a capacitor is formed by processing the upper electrode.

FIG. 14 shows the leakage current characteristic of the capacitor. FIG. 14 also shows the characteristics of the capacitors having varied thicknesses of the TiO film for second protective film 114. References P, Q, and R in the figure indicate the film thicknesses of 0.5 nm, 1 nm, and 2 nm, respectively. Reference F indicates the characteristic of a capacitor having no second protective film 114, as described in FIGS. 8, 9 and 10. As obviously depicted in the figure, second protective film 114 has an effect of reducing leakage current with respect to a low electric field (±2 V range). The applied voltage of +1 V indicates 8E−8 (A/cm²) for Reference F without second protective film 114, 3E−8 (A/cm²) for Reference P with second protective film 114 having 0.5 nm film thickness, 9E−9 (A/cm²) for Reference Q with second protective film 114 having 1 nm film thickness, and 8E−9 (A/cm²) for Reference R with second protective film 114 having 2 nm film thickness. This shows that the leakage current decreases as the film thickness increases. However, when the film thickness is 2 nm (Reference R), the effect of reducing leakage current tends to be saturated, and thus a film thickness thicker than 2 nm would not further reduce leakage current. The applied voltage of −1 V indicates 2E−7 (A/cm²) for Reference F, 2E−7 (A/cm²) for Reference P, 6E−8 (A/cm²) for Reference Q, and 3E−8 (A/cm²) for Reference R. This shows that the leakage current decreases as the film thickness increases. Although not shown in the figure, when the thickness of second protective film 114 is made as thin as 0.3 nm, it has the same value within the range of ±1 V as in the case without second protective film 114 (Reference F). Therefore, if the film thickness is 0.3 nm or less, the leakage current would not be further reduced. If the film thickness is over 2.0 nm, the effect of reducing leakage current is saturated. Based on the results above, the thickness of the TiO film as second protective film 114 is preferably 0.4 to 2.0 nm to achieve the effect of further reducing the leakage current of dielectric film 115.

The EOT with respect to each capacitor above is 0.70 nm for Reference F without second protective film 114, 0.74 nm for 0.5 nm thickness of the second protective film (Reference P), 0.82 nm for 1.0 nm film thickness (Reference Q), and 0.83 nm for 2.0 nm film thickness (Reference R). Therefore, an EOT increases monotonously as the thickness of the TiO film increases within the range from 0 to less than 1.0 nm. An EOT tends to be saturated within the range of 1.0 to 2.0 nm. That is, the contribution of second protective film 114 before and after heat treatment on a leakage current and an EOT shows the same change as that of first protective film 116. In other words, second protective film 114 functions as a dielectric within the range of its film thickness less than 1.0 nm, and functions as a conductor within the range of its film thickness of 1.0 to 2.0 nm.

Therefore, within the range of second protective film 114 of less than 1.0 nm, a heat treatment for forming upper electrode 117 causes the ZrO film for dielectric film 115 and the TiO film (when its thickness is 1 nm or more) for first protective film 116 to change into a polycrystalline state, and does not cause second protective film 114 to crystallize. Within the range of second protective film 114 of 1 nm or more, a heat treatment for forming upper electrode 117 causes the TiO film for second protective film 114, the ZrO film for dielectric film 115, and the TiO film (when its thickness is 1 nm or more) for first protective film 116 to change into a polycrystalline state. First protective film 116 remains amorphous state when its film thickness is less than 1 nm.

A capacitor in this experiment includes lower electrode 102 connected to semiconductor substrate 101, second protective film 114 formed on lower electrode 102, dielectric film 115 formed on the second protective film 114, first protective film 116 formed on dielectric film 115, and upper electrode 117 formed on first protective film 116.

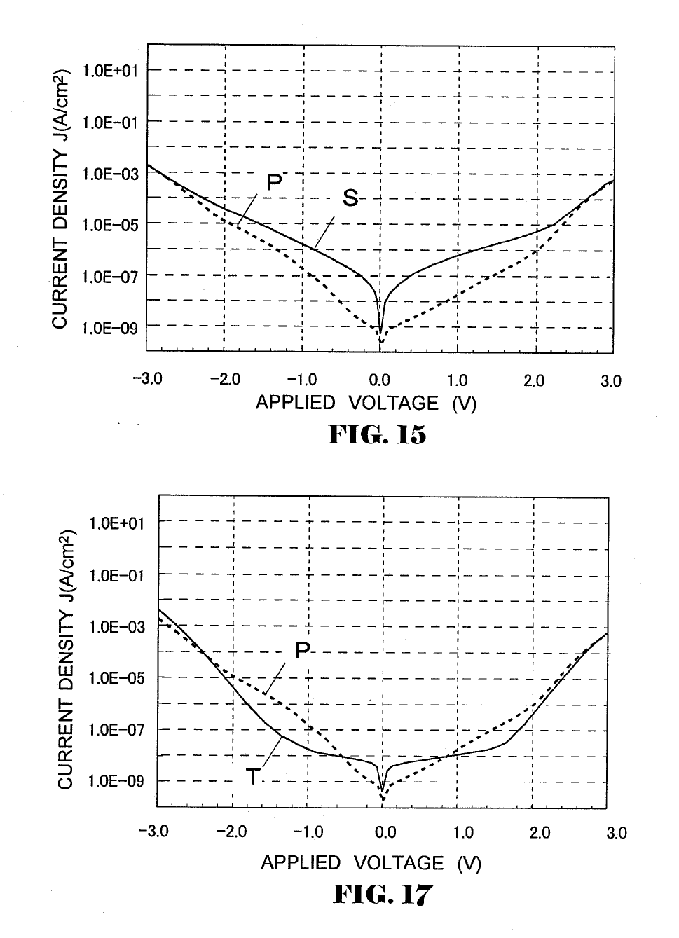

FIG. 15 is a view to explain the effect of first protective film 116 in this experiment. FIG. 15 shows the leakage current characteristic when a capacitor is fabricated to have the TiO film, which is to be second protective film 114, having a film thickness of 0.5 nm, and is heat treated at 400° C. for ten minutes under nitrogen atmosphere before forming the TiO film for the first protective film. The result is indicated by Reference S. Reference P is identical to Reference P in FIG. 14, and is associated with the result from a heat treatment during the formation of upper electrode 117 after the formation of the TiO film for first protective film 116. As obviously stated in the figure, Reference S, which indicates the result from a heat treatment performed before forming the TiO film for first protective film 116, shows an increase in leakage current, compared to Reference P, and thus represents the occurrence of cracks in the ZrO film that is to be dielectric film 115.

FIG. 15 shows the results from a heat treatment at 400° C., but an increase in leakage current at 350° C. is also acknowledged in this experiment like in the experiment 2. However, a heat treatment at 300° C. does not cause a change in leakage current. Therefore, in a capacitor structure in this experiment, it is also required to maintain the process temperature as a temperature not higher by 70° C. than the film forming temperature of the ALD method for the mc-ZrO film, until the formation of the TiO film that is to be the first protective film after forming the mc-ZrO film that is to be the dielectric film. Preferably, it is important to maintain a temperature of 300° C. or less.

### (Experiment 4)

In Experiments 1 to 3, the formation of the TiO film for the protective film(s) and the formation of the ZrO film for the dielectric film are performed in different film formation apparatus. In this experiment, with respect to the capacitor structure depicted in FIG. 13, the TiO film for second protective film 114, the ZrO film for dielectric film 115 and the TiO film for first protective film 116 are continuously formed by an ALD method in the same apparatus. It is now explained a method for manufacturing a capacitor as such and its characteristic.

First, as in Experiments 2 and 3, semiconductor substrate 101 is installed in a TiN film forming apparatus, and a CVD-TiN film the lower electrode 102 is formed on semiconductor substrate 101. The film is formed by a CVD method using reaction gases of TiCl₄ and NH₃ in consideration of the application to a three-dimensional structure as stated in Experiment 1. The film forming temperature can be set within the range of 380° C. to 600° C., and preferably 450° C. in this experiment. The film thickness is 10 nm. This TiN film is in a polycrystalline state at the film forming stage. After forming the TiN film, the substrate is taken out of the TiN film forming apparatus.

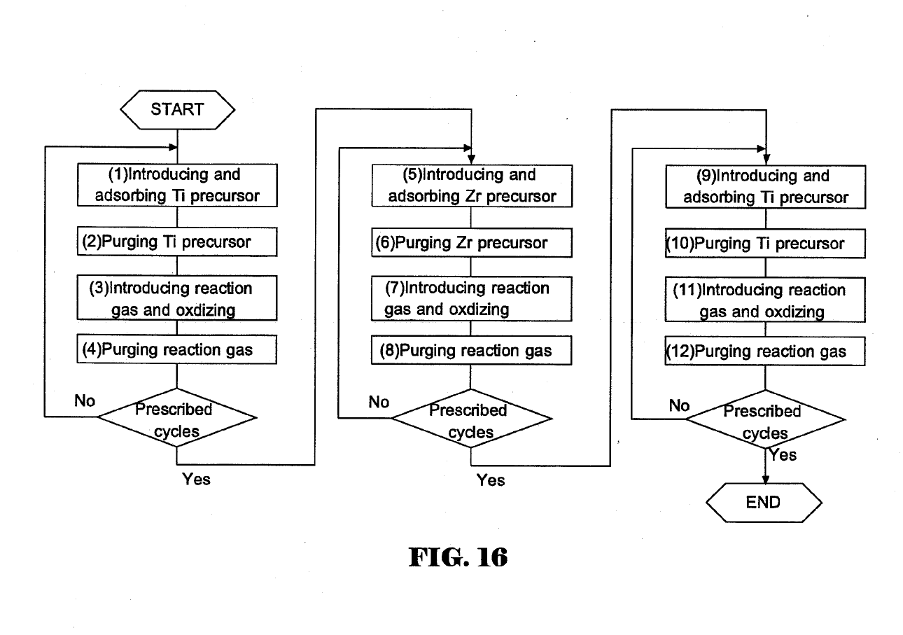

Then, the resultant semiconductor substrate is installed in an ALD film forming apparatus, and then, based on the process steps described in FIG. 16, a TiO film for second protective film 114, a ZrO film for dielectric film 115, and a TiO film for first protective film 116 are continuously laminated. All film forming temperatures were set 250° C.

First of all, the TiO film that is to be second protective film 114 is formed on lower electrode 102. The film is formed to have a thickness of 0.5 nm by an ALD method at 250° C. with a reaction gas of ozone and a Ti precursor of TTIP (titanium tetraisopropoxide: Ti(OCHMe₂)₄). Specifically, the film forming process by the ALD method includes the steps of, when the film forming process commences, (1) introducing a Ti precursor in a reaction chamber where a semiconductor substrate is installed and then adsorbing the Ti precursor on the surface of the lower electrode as an atomic layer, (2) nitrogen-purging the remaining, unadsorbed Ti precursor in a gas phase, (3) introducing ozone and oxidizing the adsorbed Ti precursor to form a TiO film and (4) nitrogen-purging the remaining, unreacted ozone and the volatile reaction products generated by the oxidization reaction in a gas phase. The film formation is developed by repeating, a predetermined number of times, the fundamental sequence including the steps (1) to (4) until the film has a thickness of 0.5 nm. The TiO film formed by the ALD method is in an amorphous state.

After forming the TiO film that is to be second protective film 114 having 0.5 nm thick by repeating a predetermined number of cycles, the ZrO film that is to be dielectric film 115 is continuously formed while remaining in the same ALD film forming apparatus. The film is formed using an ALD method at 250° C. with a reaction gas of ozone and a Zr precursor of TEMAZ (tetrakis(ethylmethylamino)zirconium:Zr[N(CH₃)CH₂CH₃]₄) so as to have a film thickness of 6 nm. Specifically, the film forming process by the ALD method includes the steps of (5) introducing the Zr precursor in the reaction room and then adsorbing the precursor on the surface of the TiO film that is to be the first dielectric film 114 as an atomic layer, (6) nitrogen-purging the remaining, unadsorbed Zr precursor in a gas phase, (7) introducing ozone and oxidizing the adsorbed Zr precursor to form a ZrO film, and (8) nitrogen-purgin the remaining, unreacted ozone and the volatile reaction products generated by the oxidization reaction in a gas phase. The ZrO film is formed by repeating, a predetermined number of times, the fundamental sequence including the steps (5) to (8) until the film has a thickness of 6 nm. The ZrO film formed by the ALD method is in a microcrystalline state.

After forming the ZrO film that is to be dielectric film 115 having 6 nm thickness by repeating a predetermined number of cycles, a TiO film that is to be first protective film 116 is continuously formed while remaining in the same ALD film forming apparatus. Although TTIP, which has been used for forming the TiO film that is to be second protective film 114, can be used as a Ti precursor, TiMCTA (methylcyclopentadienyl trisdimethylaminotitanum: (MeCp)Ti(NMe₂)₃) is used here. Ozone is used for a reaction gas, and an ALD method is carried out at 250° C. to form a film thickness of 1 nm. Specifically, the film forming process by the ALD method includes the steps of (9) introducing the Ti precursor in the reaction chamber and then adsorbing the precursor the surface of the ZrO film that is to be dielectric film 115 as an atomic layer, (10) nitrogen-purging the remaining, unadsorbed Ti precursor in a gas phase, (11) introducing ozone and oxidizing the adsorbed Ti precursor to form a TiO film, and (12) nitrogen-purging the remaining, unreacted ozone and the volatile reaction products generated by the oxidation reaction in a gas phase. The TiO film that is to be first protective film 116 is formed by repeating, a predetermined number of times, the fundamental sequence including the steps (9) to (12) until the film has a thickness of 1 nm. First protective film 116 formed by the ALD method is in an amorphous state. Once the formation of the TiO film that is to be first protective film 116 is complete, the film formation process is over and the resultant semiconductor substrate is taken out of the ALD film forming apparatus.

Then, the semiconductor substrate is installed in a TiN film forming apparatus, and the TiN film that is to be upper electrode 117 is formed. As in lower electrode 102, the TiN film that is to be upper electrode 117 is formed by a CVD method using reaction gases of TiCl₄ and NH₃ in consideration of the application to a three-dimensional structure. The film forming temperature can be set in the range of 380° C. to 600° C., and preferably 450° C. in this experiment. The film thickness is 10 nm. This TiN film is in a polycrystalline state at the film forming stage. After that, as in Experiment 2, a capacitor is fabricated by processing the upper electrode.

Reference T in FIG. 17 shows the leakage current characteristic of the capacitor continuously laminated with, based on the steps of FIG. 16, the TiO film for second protective film 114 (0.5 nm in thickness), the ZrO film for dielectric film 115 (6 nm in thickness), and the TiO film for first protective film 116 (1 nm in thickness). At the stage of forming upper electrode 117, the ZrO film and the TiO film for first protective film 116 change in a polycrystalline state. Reference P in the same figure is the result from forming the three different films in different film forming apparatuses, and is identical to Reference P in FIGS. 14 and 15.

As clearly depicted in FIG. 17, the capacitor with the three different films formed in the same ALD film forming apparatus has a reduced leakage current within the ranges of the applied voltage of ±2 V, compared to the event where the films are formed in different film forming apparatuses. In particular, the leakage current characteristic improves more at the negative bias side. As a result, the applied voltage for the index of 1E−7 (A/cm²) expands from +1.4 V to +1.8 V at the positive bias side, and from −0.9 V to −1.5 V at the negative bias side. The margin largely expands with respect to the index of ±1 V. In this experiment, the EOT is 0.73 nm, and corresponds to the EOT of 0.74 nm obtained from a capacitor having a physical film thickness structure as described in Experiment 3. As such, in this experiment, a capacitor continuously formed with the TiO film for second protective film 114 (0.5 nm in thickness), the ZrO film that for dielectric film 115 (6 nm in thickness) and the TiO film for first protective film 116 (1 nm in thickness) can have the leakage current in dielectric film 115 reduced with the EOT constant.

Although it is not obvious why the continuous film forming process in this experiment improves the leakage current characteristic, the reason is qualitatively thought as follows. FIG. 17 shows that although the improvement by the continuous film formation appears at the positive bias side, it is more remarkable at the negative bias side. That is, when a negative bias is applied to the upper electrode, the improvement is noticeable. The application of a negative bias to the upper electrode means the injection of electrons from the upper electrode. Therefore, if a factor which lowers the potential barrier formed between the upper electrode and the dielectric exists on the interface, the leakage current increases. In Experiment 3, a conveying process between film forming apparatuses is required because the TiO film that for first protective film 116 is formed in another ALD film forming apparatus after forming the ZrO film for dielectric film 115. During this conveying process, if organic matters existing in the surroundings are attached to the surface of the semiconductor substrate, i.e., the surface of the ZrO film, a TiO film is formed thereon to form first protective film 116. As a result, the organic matters remaining on the interface is thought to be a factor to lower the potential barrier. In this experiment, the films are formed in a single ALD film forming apparatus and do not require a conveying process. Because there is no attachment of organic matters, the leakage current decreases. Furthermore, because this experiment has a more remarkable improvement at the negative bias side, it is desirable to continuously perform the process of forming dielectric film 115 and the process of forming first protective film 116. In this experiment, the film formations are continuously performed in one ALD film forming apparatus and all have the film forming temperature of 250° C. Therefore, the whole process does not include a heat treatment at a temperature higher by 70° C. than the film formation temperature by the ALD method for the dielectric film between the formation of the ZrO film for dielectric film 115 and the formation of the TiO film for first protective film 116.

In this experiment, TTIP or TiMCTA is used for a Ti precursor, and TEMZA is used for a Zr precursor. Using these precursors allows the film formation at the same temperature. Therefore, the TiO film, ZrO film and TiO film can be continuously formed without changing the temperature in the film forming apparatus, and thus a decline in production efficiency can be advantageously avoided. The above precursors are not exclusive, but may include any precursor which allows a film formation at the same temperature.

### (Experiment 5)

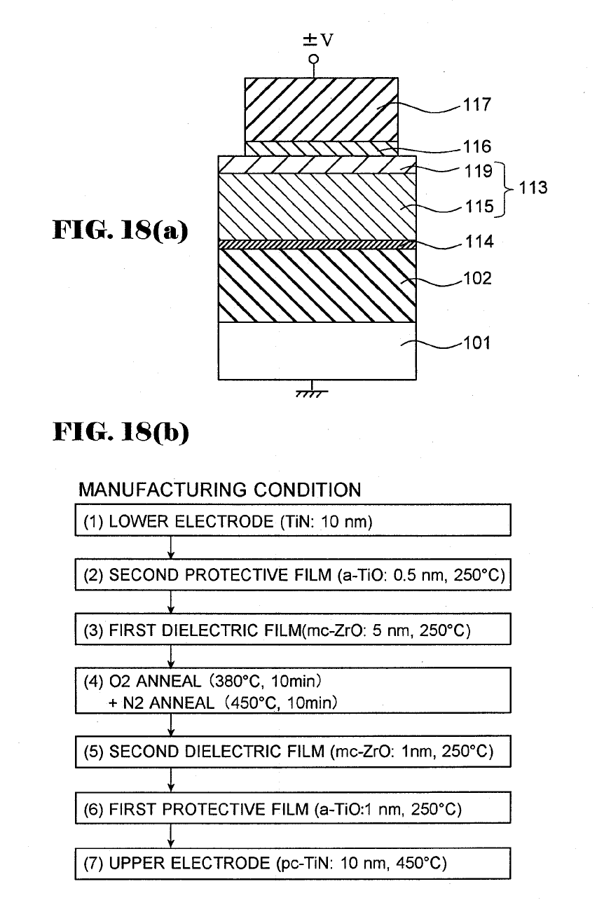

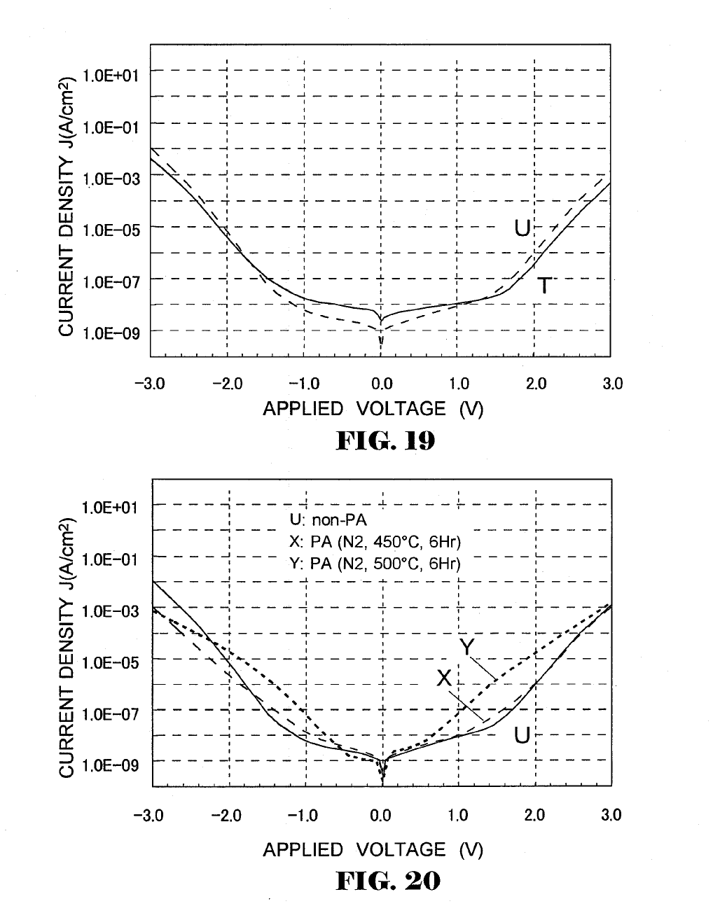

In this experiment, the characteristic of a capacitor having a ZrO film formed by two steps, as a way of forming the dielectric film, is described with reference to FIGS. 18 and 19. The method used here includes forming a first mc-ZrO film, poly-crystallizing the film by heat treatment, forming a second mc-ZrO film thereon, laminating an a-TiO film thereon as a first protective film, and changing the second mc-ZrO film and the a-TiO film for the first protective film (when the film thickness is 1 nm or more) into a polycrystalline state by heat treatment during the upper electrode formation.

FIG. 18(a) shows the structure of a capacitor in this experiment. The capacitor structure includes, on semiconductor substrate 101 of silicon monocrystal, lower electrode 102 made of a CVD-TiN film, second protective film 114 made of an a-TiO film having 0.5 nm thickness, first dielectric film 115 made of a pc-ZrO film having 5 nm thickness, second dielectric film 119 made of a pc-ZrO film having 1 nm thickness, first protective film 116 formed on second dielectric film 119 and made of a pc-TiO film having 1 nm thickness, and upper electrode 117 formed on first protective film 116 and made of a CVD-TiN film.

The capacitor in this experiment is substantially identical to Experiments 3 and 4 except that dielectric film 113 composed of two layer films of first dielectric film 115 and second dielectric film 119. Second dielectric film 119 can use the same material, i.e., a ZrO film, as that of first dielectric film 115. Second dielectric film 119 can also use a different material, such as a hafnium oxide film or a tantalum oxide film, from that of first dielectric film 115. When the same material, i.e., zirconium oxide, is used for the first and second dielectric films, first dielectric film 115 and second dielectric film 119 are integrally formed. Therefore, the structure in this case is structurally identical to that in Experiment 3 of FIG. 13.

Now, a method for forming a capacitor depicted in FIG. 18(a) is explained with reference to FIG. 18(b).

(1) Step for Forming the Lower Electrode

First, as in Experiment 4, semiconductor substrate 101 is installed in a TiN film forming apparatus, and a CVD-TiN film for lower electrode 102 is formed on semiconductor substrate 101. The film is formed by a CVD method with reaction gases of TiCl₄ and NH₃ in consideration of the application to a three-dimensional structure. The film forming temperature is 450° C., and the film thickness is 10 nm. This TiN film is in a polycrystalline state at the film forming stage. After forming the TiN film, the substrate is taken out of the TiN film forming apparatus.

(2) Step of Forming a TiO Film for the Second Protective Film

Then, semiconductor substrate 101 is installed in an ALD film forming apparatus, and a TiO film for second protective film 114 is formed based on the process steps illustrated in FIG. 16. The film is formed by an ALD method at 250° C. with a reaction gas of ozone and a Ti precursor of TTIP (titanium tetra isopropoxide: Ti(OCHMe₂)₄) so as to have a thickness of 0.5 nm. The TiO film at the film forming stage by the ALD is in an amorphous state.

(3) Step of Forming a ZrO Film for the First Dielectric Film

After forming second protective film 114, a ZrO film for first dielectric film 115 is continuously formed with the substrate remaining in the same ALD film forming apparatus. The film is formed by an ALD method at 250° C. with a reaction gas of ozone and a Zr precursor of TEMAZ, i.e., tetrakis(ethylmethylamino) zirconium:Zr[N(CH₃)CH₂CH₃]₄) so as to have a thickness of 5 nm. The ZrO film formed by the ALD method is in a microcrystalline state.

(4) Heat Treatment Step

After forming first dielectric film 115, the substrate is heat treated at an increased temperature of 380° C. under oxygen atmosphere (O2 anneal) for ten minutes with the substrate remaining in the same ALD film forming apparatus. After that, the temperature is adjusted to rise to 450° C., and a further heat treatment is performed under nitrogen atmosphere (N2 anneal) for ten minutes. At this stage, the ZrO film for first dielectric film 115 becomes to a polycrystalline state, and causes cracks as depicted in FIG. 5. The TiO film for second protective film 114 maintains its amorphous state.

(5) Step for Forming a ZrO Film for the Second Dielectric Film

After performing the heat treatment, the temperature is adjusted to decrease to 250° C., a ZrO film for second dielectric film 119 is formed on the entire surface of the first dielectric film having cracks generated. The film is formed by an ALD method at 250° C. with a reaction gas of ozone and a Zr precursor of TEMAZ so as to have a thickness of 1 nm. The ZrO film formed by the ALD is in a microcrystalline state.

(6) Step for Forming a TiO Film for the First Protective Film

After forming the mc-ZrO film for second dielectric film 119, a TiO film for first protective film 116 is continuously formed with the substrate remaining in the same ALD film forming apparatus. TiMCTA (methylcyclopentadienyl trisdimethylamino titanum: (MeCp)Ti(NMe₂)₃) is used for a Ti precursor. Ozone is used for a reaction gas, and an ALD method is performed at 250° C. The film thickness is 1 nm. The TiO film formed by the ALD method is in an amorphous state.

(7) Step for Forming the Upper Electrode

After forming the a-TiO film for first protective film 116, semiconductor substrate 101 is taken out of the ALD film forming apparatus, and then is installed in a TiN film forming apparatus. Subsequently, a CVD-TiN film is formed on the surface of the a-TiO film for first protective film 116. The CVD-TiN film is formed by a CVD method with reaction gases of TiCl₄ and NH₃ in consideration of the application to a three-dimensional structure. The film forming temperature is 450° C., and the thickness is 10 nm. This TiN film is in a polycrystalline state at the film forming stage. At this stage, the mc-ZrO film for second dielectric film 119 and the a-TiO film for first protective film 116 change into a polycrystalline state. After that, a capacitor is fabricated by processing the upper electrode with the upper electrode pattern, as stated in Experiment 2.

Reference U in FIG. 19 shows the leakage current characteristic of a capacitor fabricated according to the above method. Reference T in the same figure is identical to Reference T in FIG. 17. As described above, the capacitor using the method of forming the mc-ZrO film for first dielectric film 115, poly-crystallizing the film by heat treatment, forming the mc-ZrO film for second dielectric film 119 thereon, laminating the a-TiO film for first protective film 116, and changing the second dielectric film and the first protective film into a polycrystalline state by heat treatment during the formation of upper electrode 117, has the characteristic of extremely small leakage current, which corresponds to Reference T. In this experiment, after forming the mc-ZrO film for first dielectric film 115, the N2 anneal is performed at 450° C. for ten minutes in addition to the O2 anneal at 380° C. for ten minutes. Although not shown in the figure, the same result can be accomplished only by the N2 anneal at 450° C. for ten minutes. As illustrated in FIG. 15, despite a TZT structure, a leakage current increases if a heat treatment is performed at 400° C. under nitrogen atmosphere for ten minutes before forming first protective film 116. However, as in the present experiment, it is found that an increase in leakage current can be avoided by forming the mc-ZrO film for second dielectric film 119 after poly-crystallizing the mc-ZrO film for first dielectric film 115 by heat treatment. In this experiment, t the mc-ZrO film for first dielectric film 115 has a thickness of 5 nm and the mc-ZrO film for second dielectric film 119 is 1 nm in film thickness. If the upper electrode is formed after performing heat treatment at 450° C. to a ZrO film made of a single layer film having a thickness of 6 nm, the leakage current increases remarkably as in FIG. 3. Furthermore, an increase in leakage current is assumed to result from the generation of cracks occurred with the secondary growth of crystal grains as depicted in FIG. 4. In this experiment, although cracks are generated in the pc-ZrO film for first dielectric film 115 by performing heat treatment at 450° C. after forming the mc-ZrO film for first dielectric film 115, the mc-ZrO film for second dielectric film 119 formed thereafter fills the cracks generated in t the pc-ZrO film for first dielectric film 115 to remove the cracks. After the mc-ZrO film for second dielectric film 119 is formed, the a-TiO film of first protective film 116 is continuously formed. Subsequently, upper electrode 117 is formed at 450° C. Because the mc-ZrO film for second dielectric film 119 is covered with the a-TiO film of first protective film 116, the generation of new cracks in second dielectric film 119 during changing from the microcrystalline state to the polycrystalline state at the stage of forming upper electrode 117 at 450° C. is effectively suppressed.

Next, an EOT obtained from the capacitor in this experiment is explained. The capacitor in this experiment is fabricated by performing the N2 anneal at 450° C. for ten minutes, in addition to the O2 anneal at 380° C. for ten minutes, after forming the mc-ZrO film for first dielectric film 115. This capacitor has an EOT of 0.67 nm. Although not shown in the figure, a sample performed only the N2 anneal at 450° C. for ten minutes corresponds to Reference U in leakage current, and has an EOT of 0.71 nm. A sample without performing a heat treatment between the formation of the mc-ZrO film for the first dielectric film and the formation of the mc-ZrO film for the second dielectric film has an EOT of 0.74 nm. A capacitor including a single layer of the ZrO film with 6 nm in thickness, as indicated by Reference T in FIG. 19, has an EOT of 0.73 nm (see Experiment 4). In other words, with respect to the ZrO film, it is advantageous, for the purpose of minimizing the EOT, to preliminarily perform a heat treatment separately from a heat treatment for forming the upper electrode. In particular, it is more effective to perform heat treatment in an oxidative environment. A heat treatment in an oxidative environment is thought to promote the effect of removing the impurities contained in the ZrO film, and to improve the permittivity. However, if a heat treatment in an oxidative environment is performed at an excessively high temperature, the lower electrode may be oxidized by the diffusion of an oxidizing agent. Therefore, the temperature of the heat treatment is preferably within the range of 350° C. to 380° C. A temperature below 350° C. may not lead to the above effect of the heat treatment.

As described above, after forming the mc-ZrO film having 5 nm thick for first dielectric film 115, a heat treatment is first performed. Accordingly, the mc-ZrO film changes into a polycrystalline state so as to generate cracks, but portions of the film other than the cracks are densified so that the permittivity improves. When the mc-ZrO film having 1 nm thick for second dielectric film 119 is formed on the surface of thus first dielectric film, the mc-ZrO film fills up, and remove, the cracks generated in the pc-ZrO film of first dielectric film 115. The mc-ZrO film for second dielectric film 119 and the a-TiO film of first protective film 116 are subsequently formed before the formation of upper electrode 117 at 450° C. Therefore, the a-TiO film functions as a protective film for the mc-ZrO film for second dielectric film 119, and thus suppresses the generation of new cracks in the pc-ZrO film as second dielectric film 119. As a result, the method according to this experiment can maintain a low level of leakage current and reduce an EOT at the same time. Moreover, as described later, the method according to this experiment can suppress the deterioration of leakage current characteristic by a heat treatment, for a relatively long period of time, to dielectric film 113, after forming the TiN film for upper electrode 117.

The mc-ZrO film for first dielectric film 115 is 5 nm in thickness and the mc-ZrO film for second dielectric film 119 is 1 nm in thickness in this experiment, but they can vary. It is desirable to make the mc-ZrO film for the first dielectric film thicker and the mc-ZrO film for the second dielectric film thinner to promote the densification of the ZrO films. However, the mc-ZrO film for the second dielectric film is preferably at least 1 nm in thickness for filling up and removing the cracks generated in the pc-ZrO film that is the first dielectric film. As mentioned above, the thickness of the ZrO films in total is preferably 7 nm or less to maintain an EOT to be 0.9 nm or less. Therefore, for a capacitor in this experiment, it is better to form first protective film 116 with a thickness of 0.4 to 5.0 nm, the TiO film for second protective film 114 with a thickness of 0.4 to 2.0 nm, and the ZrO film for second dielectric film 119 with a thickness of 1.0 to 1.5 nm, and then to select the thickness of the ZrO film for first dielectric film 115 so as for the total thickness of the ZrO films to be within 5 to 7 nm.

The present experiment includes forming a lower electrode made of a TiN film on a semiconductor substrate, forming a second TiO film for a second protective film on the surface of the lower electrode, forming a first microcrystalline ZrO film on the surface of the second TiO film, changing at least the first microcrystalline ZrO film into a first dielectric film made of a polycrystalline ZrO film by heat treatment, forming a second dielectric film in a microcrystalline state on the surface of the first dielectric film, forming a first amorphous TiO film for a first protective film on the surface of the second microcrystalline dielectric film at a temperature at which a secondary growth of crystal grains of the second dielectric film does not occur, changing at least the second dielectric film into a second polycrystalline dielectric film by heat treatment after forming the first amorphous TiO film, and forming an upper electrode made of a TiN on the surface of the first protective film. Although the processes from the second protective film to the first amorphous TiO film for the first protective film are performed in the same ALD film forming apparatus in this experiment, they can be performed in different film forming apparatuses.

### (Experiment 6)

In this experiment, the result of performing a post annealing (PA) for a capacitor formed according to the method in Experiment 5 is described with reference to FIG. 20.

As mentioned above, the miniaturization of each memory cell, accompanied by the high integration of semiconductor memory device, requests the three-dimensional manufacturing of a capacitor. In this case, a particular process is required to manufacture this three-dimensional structure. For example, the process includes additionally forming a second upper electrode on upper electrode 117 as described in Experiments 2 to 5. In this step, for example, heat load may be caused for about six hours at as high as 500° C. In this case, a heat treatment is additionally performed to the capacitor formed according to Experiments 2 to 5. Therefore, a capacitor having a three-dimensional structure requiring the second upper electrode should necessarily have resistance against the heat treatment.

Reference U of FIG. 20 is identical to Reference U of FIG. 19 and does not perform a PA. Reference X is the result of a heat treatment under nitrogen atmosphere at 450° C. for six hours. Reference Y is the result of a heat treatment under nitrogen atmosphere at 500° C. for six hours. In the meantime, samples performing an additional heat treatment under hydrogen atmosphere at 450° C. for two hours in addition to the heat treatment under nitrogen atmosphere were evaluated, but have no difference from the results of FIG. 20. As such, it was found that a heat treatment under nitrogen atmosphere governs the characteristic change.

As obviously depicted in FIG. 20, Reference X indicating a heat treatment at 450° C. shows some increase in leakage current at a low electric field, but no remarkable change within ±1 V. The EOT of this sample is 0.68 nm, which has no big difference from the EOT of Reference U of 0.67 nm. Therefore, a capacitor indicated by Reference X has a sufficient resistance to a PA at 450° C. Although not shown in the figure, this resistance is also possessed by a capacitor having the single layer ZrO film as described in Experiment 4, and therefore the TZT structure has a resistance to a PA at 450° C. Reference Y indicating a heat treatment at 500° C. clearly shows an increase in leakage current, compared to Reference U including no PA. However, this case also shows that the leakage current is 1E−7 (A/cm²) or less with respect to ±1 V, which is a sufficiently sustainable level in use. The EOT of this sample is 0.75 nm.

Because Experiment 5 has only a heat treatment to the mc-ZrO film for first dielectric film 115 at as high as 450° C., it is assumed that the densification of the ZrO film is sufficient against a PA at 450° C., but insufficient against a PA at 500° C. Therefore, it is inferred that if the heat treatment to the first dielectric film is previously performed at 500° C., the densification would improve, and a sufficient resistance against a PA at 500° C. would be accomplished to suppress an increase in leakage current.

As shown above, a sufficient resistance against a PA can be obtained, as well as a stably maintained low leakage current level and a reduced EOT, by the method described in Experiment 5. A capacitor having the PA resistance generally has high reliability. Thus, a capacitor fabricated according to the method of Experiment 5 can be used as a component of semiconductor memory device requiring high reliability. Although it has been explained in this experiment that a TZT structure of Experiment 5 (the amorphous or polycrystalline TiO film of the first protective film/the polycrystalline TiO film of the second dielectric film 119/the polycrystalline ZrO film of the first dielectric film 115/the amorphous or polycrystalline TiO film of the second protective film 114) is treated by a PA, the structure of Experiments 2 to 4 can also obtain the PA resistance due to first protective film 116.

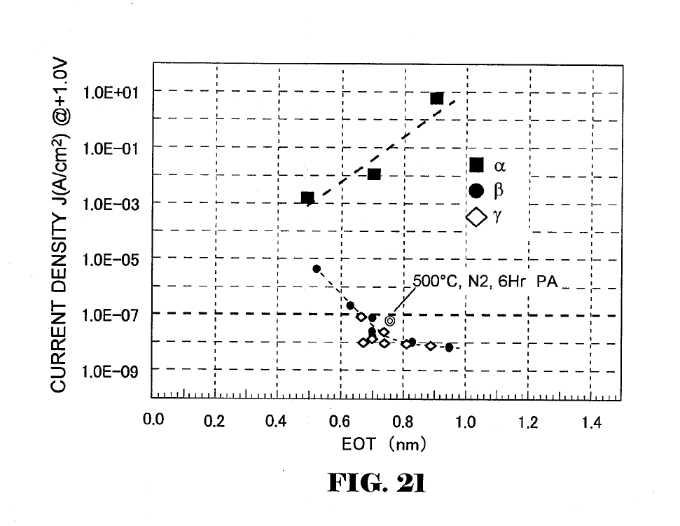

FIG. 21 shows the relation between an EOT and a leakage current at +1 V with respect to several capacitors fabricated in each experiment above. Reference α is a capacitor having a dielectric film made of a single layer ZrO film without a TiO film for the first protective film (Experiment 1). Reference β is a capacitor having a TZ structure with a dielectric film made of a single layer ZrO film and a TiO film for the first protective film (Experiment 2). Reference γ is a capacitor having a TZT structure made of a TiO film for the second protective film, a ZrO film for the first dielectric film or the first and second dielectric films, and a TiO film for the first protective film (Experiments 3 to 5). FIG. 21 also shows the result of performing a PA under nitrogen atmosphere at 500° C. for six hours with respect to a TZT structure (Experiment 6).

As clearly depicted in FIG. 21, it is obvious that a capacitor having no TiO film for the first protective film has an EOT within an allowable level, but has so a large leakage current as not to be used as a semiconductor memory device. With respect to the TZ structure and the TZT structure having a TiO film as a protective film for preventing the generation of cracks in the ZrO film, it is obvious to achieve the effect of reducing the leakage current below 1E−7 (A/cm²) at ±1 V while maintaining an EOT of 0.9 nm or less, because of forming at least a TiO film as the first protective film.

### Exemplary Embodiments 1 to 4

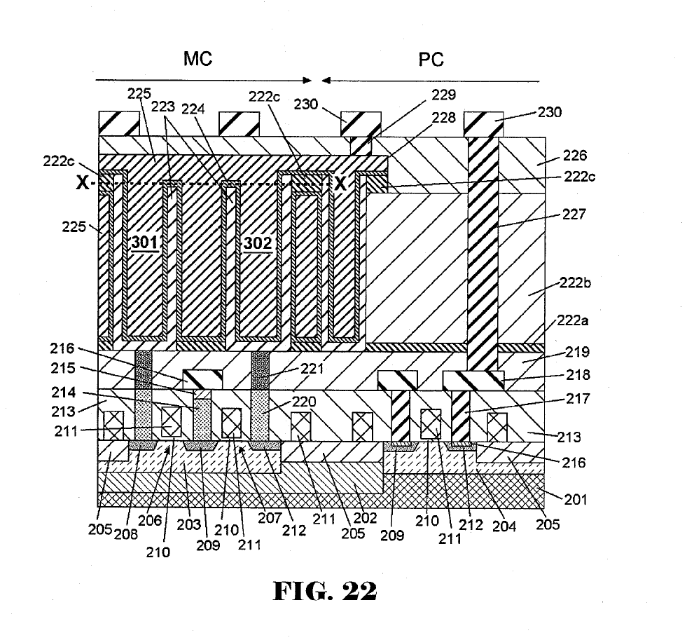

In these embodiments, a semiconductor memory device in which a capacitor structure described in Experiment 6 (using the laminating layer structure of the dielectric film and the first protective film described in Experiments 2 to 5) is applied to a three-dimensional structure is explained with reference to FIGS. 22 to 24.

Referring to a schematic cross-sectional view of FIG. 22, the entire structure of DRAM as a semiconductor memory device is generally described.

n-Well 202 is formed on p-type silicone substrate 201, and first p-well 203 is formed within n-well 202. Second p-well 204 is formed on the region with the exclusion of n-well 202, and is separated from first p-well 203 by element isolation area 205. First p-well 203 and second p-well 204 conveniently represent, respectively, memory cell area MC where a plurality of memory cells is arranged and peripheral circuit area PC.

First p-well 203 has switching transistors 206 and 207 including gate electrodes which are to be word lines with components of each memory cell. Transistor 206 includes drain 208, source 209, and gate electrode 211 with gate insulation film 210 inserted therebetween. Gate electrode 211 has a polycide structure laminating tungsten silicide on polycrystalline silicone or a polymetal structure laminating tungsten.

Transistor 207 includes common source 209, drain 212, and gate electrode 211 with gate insulation film 210 inserted therebetween. The transistor is covered by first interlayer insulation film 213.

To be connected to source 209, a contact hole installed on a certain area of first interlayer insulation film 213 is filled with polycrystalline silicone 214. Metallic silicide 215 is provided on the surface of polycrystalline silicone 214. Bit line 216 made of tungsten nitride and tungsten is provided to be connected to metallic silicide 215. Bit line 216 is covered by second interlayer insulation film 219.

For the connection to drains 208 and 212 of the transistors, contact holes are formed on a certain area of the first and second interlayer insulation films 213 and 219, and each contact hole is filled with silicone to provide silicone plug 220. Conductive plug 221 made of metal is provided on the top of silicone plug 220.

A capacitor is formed to be connected to conductive plug 221. Third interlayer insulation film 222a and fourth interlayer insulation film 222b, which are to form lower electrodes, are laminated on second interlayer insulation film 219. Fourth interlayer insulation film 222b is reserved on the peripheral circuit area, and lower electrodes 223 are formed in a crown shape on the memory cell area. Then, fourth interlayer insulation film 222b on the memory cell area is eliminated. The capacitor is configured to have dielectric film 224 which covers the outer wall exposed by removing fourth interlayer insulation film 222b and the inner wall of lower electrode 223, and upper electrode 225 which covers the entire memory cell area. Support film 222c is provided on a portion of the side of the top portion of lower electrode 223. Support film 222c is to connect some of a plurality of the adjacent lower electrodes, and thus to increase its mechanical strength and avoid the collapse of the lower electrodes themselves. Because there is a space below support film 222c, dielectric film 224 and upper electrode 225 are also provided on the surface of the lower electrodes exposed to the space. FIG. 22 depicts two capacitors 301 and 302. Lower electrode 223 is made of titanium nitride (TiN) formed by a CVD, which has an outstanding step coverage. The capacitor is covered by fifth interlayer insulation film 226. The material for the plugs is changeable depending on the lower electrode of the capacitor; the material for the plugs is not limited to silicone, but can be made of the same material as the lower electrode of the capacitor or of a different material. The structure of dielectric film 224 and upper electrode 225 is described in detail with a manufacturing process later.

A transistor, which constitutes a peripheral circuit, includes source 209, drain 212, gate insulation film 210, and gate electrode 211 on second p-well 204. A contact hole which is installed in a certain area of first interlayer insulation film 213 is filled with metallic silicide 216 and tungsten plug 217 so that the hole is connected to drain 212. First wiring layer 218 which is made of tungsten nitride and tungsten is provided to be connected to tungsten plug 217. A part of first wiring layer 218 is connected metallic via plug 227 to second wiring layer 230 made of aluminum or copper. Metallic via plug 227 is configured to penetrate second interlayer insulation film 219, third interlayer insulation film 222a, fourth interlayer insulation film 222b and fifth interlayer insulation film 226. Upper electrode 225 of the capacitor arranged in the memory cell area is withdrawn as wiring 228 from a certain area to the peripheral circuit area, and is connected to second wiring layer 230 made of aluminum or copper by intervening metallic plug 229 formed in a certain area of fifth interlayer insulation film 226. DRAM is developed by repeating the steps, as necessary, of forming interlayer insulation films, forming contacts, and forming wiring layers.

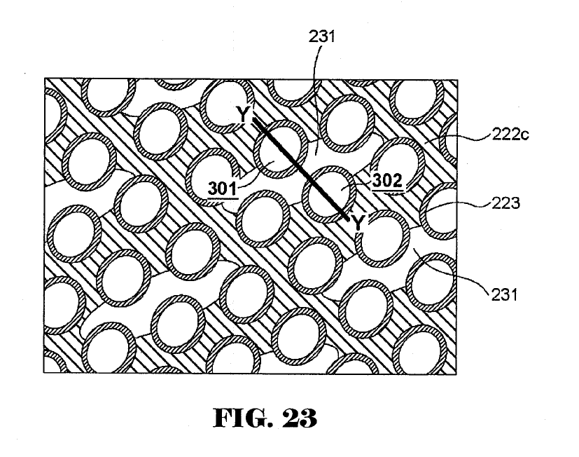

FIG. 23 is a schematic plane view of FIG. 22 taken along line X-X, excluding the dielectric film and the upper electrode. The line Y-Y in FIG. 23 corresponds to the line X-X in FIG. 22. Support film 222c, which covers the entire outside of each lower electrode 223, includes a plurality of openings 231 over the entire memory cell area in a way of extending over a plurality of the lower electrodes. Each lower electrode 223 is so configured that part of its circumference is in contact with any one of openings 231. The support film with the exclusion of the openings is continuously configured so that the lower electrodes are connected to each other via the support film. The support film also helps avoiding the collapse of the lower electrodes themselves because the film may relatively extend the horizontal length with respect to the aspect ratio, i.e., the vertical/horizontal ratio. When cells are miniaturized with a high degree of integration, the aspect ratio, i.e., the vertical/horizontal ratio, of the lower electrode of the capacitor increases, and would thus cause the collapse of the lower electrode during its manufacturing without a means to support the lower electrode. FIG. 23 shows an example of opening 231 overlapping six lower electrodes with a central focus on an area between capacitors 301 and 302. Therefore, in FIG. 22, the upper portions of capacitors 301 and 302 and of an area between the capacitors 301 and 302, which correspond to the areas in FIG. 23, are configured to have no support film.

As such, with the support film prepared, a better film forming method with a better coverage is required to form a dielectric film and an upper electrode on the surface of the lower electrode below the support film.

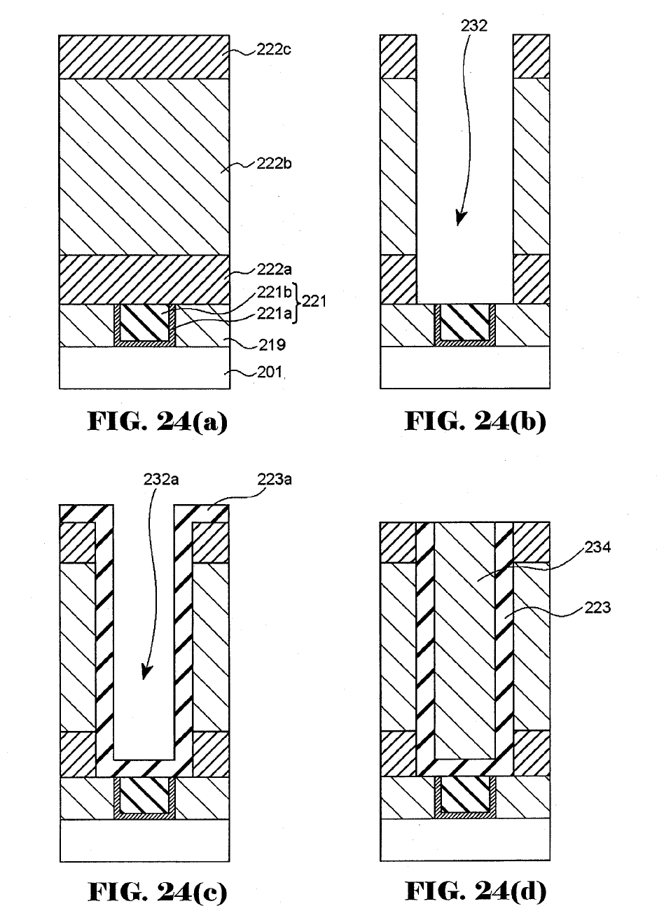

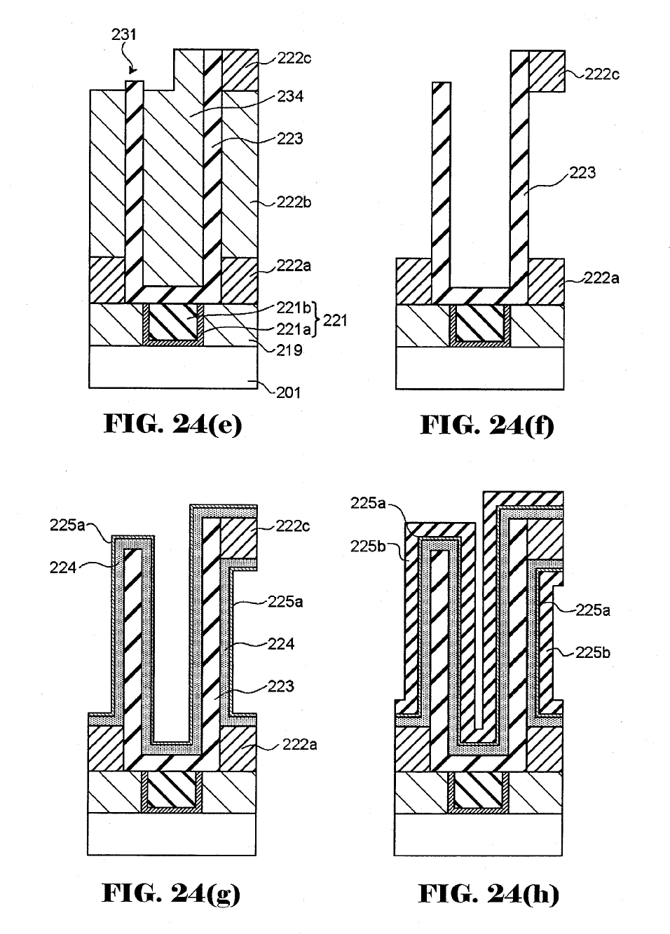

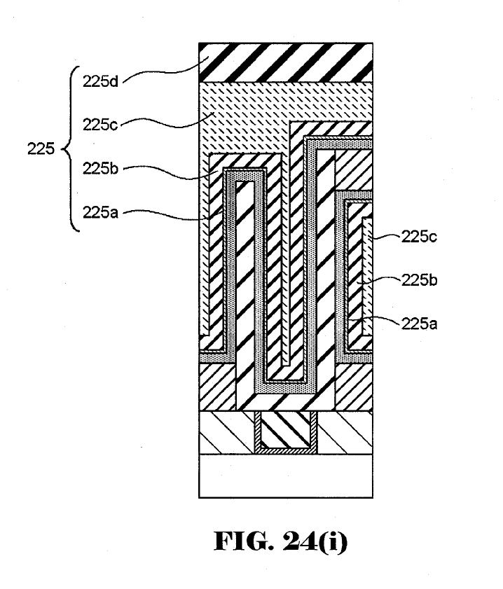

A process for manufacturing a capacitor according to the invention is now described with the exclusion of the other processes in a method of manufacturing DRAM as the semiconductor memory device described above. FIG. 24 is a cross-sectional view of a process for manufacturing one capacitor depicted in FIG. 22. For clarity, a transistor or a first interlayer insulation film on semiconductor substrate 201 is omitted.

First, as shown in FIG. 24(a), first interlayer insulation film 219 is formed on semiconductor substrate 201 made of monocrystal silicon. Then, a contact hole is formed on a predetermined location, and barrier metal film 221a and metal film 221b are formed on the entire surface. Then, barrier metal film 221a and metal film 221b, which have been formed on the second interlayer insulation film is removed by a CMP method to form conductive plug 221. Then, third interlayer insulation film 222a made of a silicon nitride film, fourth interlayer insulation film 222b made of a silicon oxide film, and support film 222c made of a silicon nitride film are formed on the entire surface.

Then, as shown in FIG. 24(b), cylinder hole 232 is formed in support film 222c, fourth interlayer insulation film 222b and third interlayer insulation film 222a by lithography and dry etching. The cylinder hole has a circular plane profile having a diameter of 60 nm. The closest distance from the adjacent cylinder hole is 60 nm. As such, the bottom surface of the cylinder hole is exposed to the top surface of conductive plug 221.

Then, as shown in FIG. 24(c), TiN film 223a, which is the material of the lower electrode of the capacitor, is formed on the entire surface including the inner surface of cylinder hole 232. The TiN film can be formed by a CVD method with source gases of TiCl₄ and NH₃ at a forming temperature between 380° C. to 650° C. The forming temperature is 450° C. and the film thickness is 10 nm in this embodiment. Alternatively, the TiN film can also be formed by an ALD method using the same source gases. The formation of TiN film 223a defines new cylinder hole 232a.

Then, as shown in FIG. 24(d), protective film 234 such as a silicon oxide film is formed on the entire surface to load cylinder hole 232a. Then, TiN film 223a and the protective film 234 formed on the top surface of the support film 222c are removed by a CMP or dry etching method to form lower electrode 223.

Then, opening 231 is formed in support film 222c (see FIG. 24(e)). As illustrated in the plane view of FIG. 23, the pattern of opening 231 overlaps with a part of fourth interlayer insulation film 222b, a part of lower electrode 223, and a part of protective film 234 remaining in the inside of the lower electrode. Therefore, dry-etching for forming opening 231 removes a portion of the top of lower electrode 223 and the protective film 234 as well as the support film 222c formed on fourth interlayer insulation film 222b.

Then, as shown in FIG. 24(f), fourth interlayer insulation film 222b exposed in opening 231 is removed. For example, an etching process using hydrofluoric acid solution (HF solution) does not substantially etch support film 222c because support film 222c is made of a silicon nitride film, but removes all of protective film 234 and fourth interlayer insulation film 222b formed with a silicon oxide film.

Besides the area right under opening 231, the silicon oxide film below support film 222c is also removed because the etching uses a solution. Accordingly, lower electrode 223 and support film 222c supporting lower electrode 223 remains hollow, and lower electrode 223 exposes its surface.

During this etching process, third interlayer insulation film 222a made of a silicon nitride film functions as an etching stopper, preventing second interlayer insulation film 219 from being etched.

Then, as shown in FIG. 24(g), dielectric film 224 and the TiO film for first protective film 225a are formed. First protective film 225a and dielectric film 224 have a TZ structure described in Experiment 2 or a TZT structure as described in Experiments 3-5 is introduce, and can be formed by an ALD method. These TZ and TZT structures are optimized to achieve a desired feature for each parameter. A film formed by an ALD method has an excellent step coverage, and thus dielectric film 224 and first protective film 225a are formed on the entire surface of the lower electrode exposed as being hollow.

Then, as shown in FIG. 24(h), a TiN film is formed as the first upper electrode 225b. Like the lower electrode, the upper electrode 225b is formed at 450° C. by a CVD method with source gases of TiCl₄ and NH₃. The film thickness is 10 nm. Because a TiN film formed by a CVD method has a very excellent step coverage, the film may invade the hollow space so that it may be formed on the entire surface of the first protective film 225a.

Because dielectric film 224 is heat-treated under the protection by a TiO or TiN film, which is first protective film 225a, although first upper electrode 225b is formed at 450° C., the problem of an increase in leakage current caused by the generation of cracks can be avoided as explained in the previous experiments.

Then, as shown in FIG. 24(i), a boron-doped silicon germanium film (B—SiGe film) is formed as second upper electrode 225c. At the stage of forming first upper electrode 225b in FIG. 24(h), a hollow state partially remains to leave spaces all around. If tungsten which is to be a plate is formed by a PVD method under this circumstance, spaces would remain around the capacitor even at the final stage of fabricating a semiconductor device because the spaces may not be all filled due to the inferior step coverage of the PVD method. These remaining spaces worsens the mechanical strength, and causes a change in the characteristic of the capacitor due to the stress occurred during the packaging of the subsequent processes. Therefore, the object of forming the B—SiGe film is to stuff, and thus eliminate, the remaining spaces and to improve resistance to mechanical stress.

The B—SiGe film can be formed by a CVD method with source gases of germane (GeH₄), silane (SiH₄) and boron trichloride (BCl₃). The B—SiGe film formed by this method has an excellent step coverage, which allows stuffing the hollow spaces. The CVD method requires 420° C. to 500° C. at a forming temperature and performs heat treatment for six hours to the capacitor when it is formed in a batch manner in consideration of productivity. The heat treatment in this process was represented by the PA in Experiment 6. Even if a heat treatment at a maximum temperature of 500° C. is performed during the process of forming a B—SiGe film for second upper electrode 225c, the capacitor according to the methods in Experiments 2 to 5 can have low leakage current, while ensuring the EOT.

After forming the B—SiGe film as second upper electrode 225c, a tungsten film (W film) is formed as third upper electrode 225d so as to be used as a power supply plate covering the entire memory cell area. Because the W film is formed by a PVD method at 25° C. to 300° C., it imposes no heat-related influence such as an increase in the dielectric film's leakage current. After that, as shown in FIG. 22, a semiconductor device including DRAM is fabricated by performing a process of forming fifth interlayer insulation film 226 and subsequent processes.

As described above, upper electrode 225 shown in FIG. 22 with the entire structure includes a polycrystalline TiN film as first upper electrode 225b, a B—SiGe film as second upper electrode 225c, and a W film as third upper electrode 225d, as depicted in detail in FIGS. 24(i). The structure and manufacturing method for a DRAM according to this embodiment are to fabricate a most-advanced, super integrated DRAM. The B—SiGe forming process is not necessary if a capacitor is a flat capacitor of a three-dimensional capacito which does not require support film 222c for preventing collapse, and the influence of a PA at 500° C. is alleviated.

When a capacitor with a TZT structure is used, the film thickness of the second protective film formed by an ALD method is limited. As explained above, the TiO film for the second protective film formed by an ALD method remains in an amorphous state when the thickness is less than 1 nm, but changes into a conductor in a polycrystalline state when the thickness is 1 nm or more. If a TiO film for the second protective film with a thickness of 1 nm or more is formed on the entire surface of lower electrode 223 after forming lower electrode 223 of FIG. 24(f), the second protective film changes into a conductor at the stage of forming upper electrode 225b so that it causes short-circuit between lower electrodes 223, thereby invalidating the function as a semiconductor memory device. Therefore, the thickness of the second protective formed by the ALD method is necessarily less than 1 nm to avoid short-circuiting. In such a case, a TiO film for the second protective film is formed to have a thickness of 1 nm or more by using an ALD method as well as oxidizing the surface of the TiN film constituting lower electrode 223. Because the oxidizing method does not oxidize anything other than the TiN film for lower electrode, a TiO film is not formed between the adjacent lower electrodes. Therefore, when the thickness of the second protective film is 1.5 nm, for example, a TiO film having 0.6 nm thick is first formed only on the surface of the TiN film of the lower electrode by the oxidizing method, and a TiO film having 0.9 nm thick is then formed by the ALD method. As a result, the crystallization of the TiO film can be avoided and the short-circuit between the lower electrodes can be prohibited because the TiN lower electrode has only a TiO film with 1.5 nm thick thereon and the TiO film with 0.9 nm thick on the insulation film between the lower electrodes maintains the amorphous state, which is not conductive.

As explained above, the present invention provides a capacitor having a low leakage current while ensuring an EOT because it can avoid the generation of cracks in the ZrO film by forming the upper electrode during a heat treatment at 450° C. while protecting the surface of the ZrO film for the dielectric film with the TiO film for the first protective film.

The prevent invention includes the following aspect of embodiment.

I. A semiconductor device comprising:

a semiconductor substrate, and

a capacitor including a lower electrode connected to said semiconductor substrate, an upper electrode and a dielectric film sandwiched between the lower and upper electrodes,

wherein the capacitor further includes a first protective film comprising a titanium oxide film provided between the dielectric film and the upper electrode, being in contact with said dielectric film, and

wherein the upper electrode includes a polycrystalline titanium nitride film being in contact with the first protective film.

II. The semiconductor device according to Item I, wherein the dielectric film comprises a polycrystalline zirconium oxide film.

III. The semiconductor device according to Item II, wherein the polycrystalline zirconium oxide film has a thickness of 5 nm to 7 nm.

IV. The semiconductor device according to items I to III, wherein the capacitor further includes a second protective film including a titanium oxide film provided between the dielectric film and the lower electrode.

V. The semiconductor device according to item IV, wherein the second protective film including a titanium oxide film has a thickness of 0.4 nm to 2 nm.

VI. The semiconductor device according to item V, wherein the second protective film comprises an amorphous titanium oxide film having a thickness less than 1 nm.

VII. The semiconductor device according to item V, wherein the second protective film comprises a polycrystalline titanium oxide film having a thickness of 1 to 2 nm.

VIII. The semiconductor device according to items I to VII, wherein the SiO₂ equivalent oxide thickness (EOT) of the dielectric film is 0.9 nm or less.

IX. The semiconductor device according to items I to VIII, wherein the first protective film has a thickness of 0.4 nm to 5 nm.

X. The semiconductor device according to item IX, wherein the first protective film comprises a polycrystalline titanium oxide film having a thickness of 1 nm to 2 nm.

XI. The semiconductor device according to item IX, wherein the first protective film comprises an amorphous titanium oxide film having a thickness of 0.4 nm or more and of less than 1 nm.

XII. The semiconductor device according to items I to XI, wherein the lower electrode has a three-dimensional structure.

XIII. The semiconductor device according to item XII, wherein the upper electrode comprises a second upper electrode made of a silicon germanium film containing boron on the polycrystalline titanium nitride film.

XIV. The semiconductor device according to items I to XIII, wherein the capacitor has a leakage current characteristic of a current density of 1E−7 (A/cm²) or less when a voltage within the range of ±1 V is applied.

What is claimed is:

1. A method for manufacturing a semiconductor device including a formation of a capacitor, wherein the formation of the capacitor comprises at least:
forming a lower electrode comprising titanium nitride on a semiconductor substrate,
forming a dielectric film comprising zirconium oxide, and
forming an upper electrode comprising titanium nitride on said dielectric film,
wherein at least the uppermost layer of said dielectric film is formed by an atomic layer deposition (ALD) method, and
wherein said formation of the capacitor further comprises, between said step of forming the dielectric film and said step of forming the upper electrode, forming a first protective film on said uppermost layer of said dielectric film without exceeding the film forming temperature of said ALD method over 70° C.

2. The method for manufacturing a semiconductor device according to claim 1, wherein the formation of said capacitor is free from a heat-treatment at a temperature higher by 70° C. than the film forming temperature of said ALD method between steps of forming said uppermost layer of said dielectric film and forming said first protective film on said uppermost layer.

3. The method for manufacturing a semiconductor device according to claim 1, wherein a process temperature is maintained at 300° C. or less from said step of forming the dielectric film on the lower electrode to said step of forming the first protective film on the dielectric film.

4. The method for manufacturing a semiconductor device according to claim 1, wherein said forming of the dielectric film is performed by an ALD method at a film forming temperature of 210° C. to 280° C.

5. The method for manufacturing a semiconductor device according to claim 4, wherein said forming of the first protective film is performed by an ALD method at a film forming temperature of 210° C. to 280° C.

6. The method for manufacturing a semiconductor device according to claim 1, wherein said first protective film comprises a titanium oxide film having a film thickness of 0.4 nm to 5.0 nm.

7. The method for manufacturing a semiconductor device according to claim 1, wherein said dielectric film comprises a single layer zirconium oxide film having a film thickness of 5.0 nm to 7.0 nm.

8. The method for manufacturing a semiconductor device according to claim 1, wherein said dielectric film is in a microcrystalline state at the stage of forming said first protective film, and
said formation of the capacitor further comprises changing said dielectric film into a polycrystalline state accompanying with a secondary growth of crystal grains by performing a heat treatment at 380° C. or higher.

9. The method for manufacturing a semiconductor device according to claim 8,
wherein said upper electrode is formed by a CVD method at a film forming temperature of 380° C. to 600° C., and
wherein said step of forming the upper electrode also serves as said step of changing the dielectric film in a microcrystalline state into a polycrystalline state.

10. The method for manufacturing a semiconductor device according to claim 1, wherein said formation of the capacitor further comprises a step of forming a second protective film on said lower electrode after said step of forming the lower electrode and before said step of forming the dielectric film.

11. The method for manufacturing a semiconductor device according to claim 10, wherein said second protective film comprises a titanium oxide film having a thickness of 0.4 nm to 2.0 nm.

12. The method for manufacturing a semiconductor device according to claim 11, wherein said second protective film is formed by an ALD method at a film forming temperature of 210° C. to 280° C.

13. The method for manufacturing a semiconductor device according to claim 1, wherein said step of forming the dielectric film includes, forming a first dielectric film made of a zirconium oxide by an ALD method, changing said first dielectric film into a densified first dielectric film by a heat treatment, and forming a second dielectric film on said densified first dielectric film by an ALD method.

14. The method for manufacturing a semiconductor device according to claim 13, wherein said second dielectric film is formed in a thickness of 1 nm to 1.5 nm, and said first dielectric film is formed to satisfy the total film thickness of said second dielectric film and said first dielectric film within 5 nm to 7 nm.

15. The method for manufacturing a semiconductor device according to claim 13, wherein said second dielectric film is the same as, or different from, said first dielectric film in kind.

16. The method for manufacturing a semiconductor device according to claim 13, wherein said heat treatment for densifying the first dielectric film includes a heat treatment in an oxidative environment at 350° C. to 380° C.

17. The method for manufacturing a semiconductor device according to claim 13, wherein a process temperature is maintained at 300° C. or less from said step of forming the second dielectric film to said step of forming the first protective film on the second dielectric film.

18. The method for manufacturing a semiconductor device according to claim 1, wherein the processes from forming the dielectric film on the lower electrode to forming the first protective film on the dielectric film are continuously performed in one film forming apparatus.

19. The method for manufacturing a semiconductor device according to claim 1, wherein said step of forming the dielectric film is a step of forming the dielectric film so that SiO₂ equivalent oxide thickness (EOT) of said dielectric film is 0.9 nm or less.

20. The method for manufacturing a semiconductor device according to claim 1, wherein said lower electrode has a three-dimensional structure.
